(19) United States
(12) Patent Application Publication
(10) Pub. No.: US 2011/0147722 A1
(43) Pub. Date: Jun. 23, 2011

(54) SEMICONDUCTOR LIGHT EMITTING DEVICE COMPRISING HIGH PERFORMANCE RESINS

(76) Inventors: Craig J. Hawker, Santa Barbara, CA (US); Hunaid Nulwala, Upper Saint Clair, PA (US); Anika A. Odukale, Reston, VA (US); Taegon Kang, Goleta, CA (US); Jeffrey A. Gerbec, Goleta, CA (US); Kenichi Takizawa, Kitakyushu-shi (JP)

(21) Appl. No.: 12/951,677

(22) Filed: Nov. 22, 2010

Related U.S. Application Data
(63) Continuation-in-part of application No. 12/580,555, filed on Oct. 16, 2009.

(51) Int. Cl. H01L 51/54

(52) U.S. Cl. 257/40; 257/E51.026

(57) ABSTRACT

A semiconductor light emitting device comprising curable polyorganosiloxane compositions is provided where the compositions contain a 13^{th} group elements of the periodic table. The cured polyorganosiloxane compositions may be catalyst-free, have increased stability, and can be used as encapsulation resin at a temperature far lower than 300° C., have excellent light transmission properties (colorless transparency) in a wavelength region of from ultraviolet light to visible light, light resistance heat resistance, resistance to moist heat and UV resistance, and has excellent adhesiveness toward metal, ceramics, and plastic surfaces over a long period of time.

### CROSS-REFERENCE TO RELATED APPLICATIONS

This application is a continuation-in-part of, and claims the benefit of, patent application Ser. No. 12/580,555, filed on Oct. 16, 2009, of which is incorporated herein by reference in its entirety.

### FIELD OF THE INVENTION

The invention relates to the semiconductor light emitting device with high transparency, high heat stability, high UV flux stability, mechanically tunable properties, suitable adhesiveness, and chemically inertness.

### BACKGROUND OF THE INVENTION

High brightness light emitting diodes (HBLEDs) offer enhanced energy efficiency thus making them suitable for specialty lighting applications. An LED device is usually composed of the LED chip fabricated onto a substrate and then encapsulated by a material acting as a lens and a luminescence conversion member. The following are the operational requirements of a material to be utilized as an encapsulant of LEDs: optical clarity, high temperature resistant, UV resistant, high refractive index and good adhesiveness toward LED packaging materials.

Encapsulant materials must be optically transparent (greater than 90% transmittance) and should be able to withstand high temperatures, for extended periods of time, without degradation in mechanical and optical performance. The LED device encounters high temperature conditions during the device fabrication (soldering up to 260° C.) and during the actual device operation (around 150° C. for thousands of hours).

To overcome those problems, a silicone resin (polyorganosiloxane) having excellent heat resistance and ultraviolet resistance was used as a substitute of the epoxy resin, which has conventionally been used for the encapsulation. However, silicone resins up to now tend to scar easily, and are not yet sufficient when considering the combined characteristics: adhesion, colorless transparency, heat resistance, resistance to moist heat and UV tolerant.

Furthermore, since a silicone resin generally has a lower gas barrier property than an epoxy resin, it tends to deteriorate an LED chip or a phosphor when used for a long period of time. On the other hand, a resin for sealing a photosemiconductor device, which is obtained by reacting a silicon compound with a boron compound or an aluminum compound for the purpose of imparting a good luminance retention, is disclosed in JP-A-2009-19104, JP-A-2009-127020, JP-A-2009-127021, and JP-A-2009-127022. However, these resins may have a small reaction rate when cured in some cases. In addition, there are cases where sufficient hardness can not be obtained when cured.

The present invention allows such properties to be achieved, as well.

### SUMMARY OF THE INVENTION

The semiconductor light emitting device of the present invention comprises a polysiloxane composition containing a 13^{th} group element of the periodic table. As the 13^{th} group element, aluminum and boron are preferable, and boron is more preferable.

The above-mentioned polysiloxane composition is obtained by reaction comprising a compound (A) containing a 13^{th} group element of the periodic table and a siloxane compound (B) so that it enhances the reaction rate or a cured product thereof has sufficient hardness.

In one embodiment, compound (B) is reacted with compound (A), where compound (A) is either one or more of a functional carborane, 2A, 2A′, U, V, W, or W′, or, any combination thereof.

### BRIEF DESCRIPTION OF THE DRAWINGS

For a more complete understanding of the present invention, reference is now made to the following descriptions taken in conjunction with the accompanying drawing, in which:

FIG. 1 shows ¹H-NMR spectrum of one example of m-Carborane based modifier.

FIG. 2 shows ¹H-NMR spectrum of one example of Boro-silicate-cage-shaped modifier.

FIG. 3 gives Thermal Gravimetric analysis (TGA) in air of m-Carborane modified RTV-615s.

FIG. 4 shows UV-VIS with time studies of 5 wt % m-Carborane modifier loaded RTV-615 isotherm at 150° C.

FIG. 5 shows thermal gravimetric analysis of resins of Example 3-1.

FIG. 6a gives UV-VIS data with m-Carborane modifier loading of 20 wt % annealed at 150° C.

FIG. 6b gives UV-VIS data with m-Carborane modifier loading of 10 wt % annealed at 150° C.

FIG. 7 shows TGA data of resins of Example 3-2 with/without m-Carborane modifier.

FIG. 8 shows TGA data of the polyorganosiloxane compositions prepared in Example 4.

FIG. 9 shows thermal durability test (150° C.) results of resins of Example 3-2 with/without m-Carborane modifier.

FIG. 10 shows thermal durability test (200° C.) results of resins of Example 3-2 with/without m-Carborane modifier.

FIG. 11 shows hydrothermal durability test (60° C./95% RH) results of resins of Example 3-2 with/without m-Carborane modifier.

FIG. 12 gives the spectrum of the original UV light source for the UV durability tests of resins. (Under 350 nm was cut off.)

FIG. 13 gives the heating-cooling profile of the Heat-Cycle tests of the resins.

FIG. 14 shows power output maintenance factor of LEDs using resins of Example 3-2 without phosphors (25° C./55% RH).

FIG. 15 shows power output maintenance factor of LEDs using resins of Example 3-2 without phosphors (60° C./90% RH).

FIG. 16 shows lumen maintenance factor of LEDs using resins of Example 3-2 with RGB-phosphors (25° C./55% RH).

FIG. 17 shows lumen maintenance factor of LEDs using resins of Example 3-2 with RGB-phosphors (60° C./90% RH).

FIG. 18 shows a UV-Vis spectra of the sample prepared in Example 6 before and after thermal stability test at 150° C. for 200 hours.

FIG. 19 shows a FTIR spectra of the sample prepared in Example 7 after completion of the reaction and NO OH peaks were observed.

FIG. 20 shows high thermal stability up to 350° C. of the siloxane aluminate samples prepared in Example 7.

FIG. 21 shows FTIR graphs of the compositions obtained in Example 8.

FIG. 22 shows thermogravamatric analysis (TGA) data of the mixed boron, zirconium siloxane aluminate materials obtained in Example 11 and all of them are found to be stable up to 350° C.

FIG. 23 shows the TGA data of the samples prepared in Example 8 and 9 showing those materials stable up to 350° C.

FIGS. 24(a) and (b) show one embodiment of the semiconductor light emitting device of the present invention.

FIG. 25 shows one embodiment of the semiconductor light emitting device of the present invention.

FIG. 26 shows a functional carborane.

FIG. 27 shows a general synthetic example of polyorganosiloxanes using hydrosilylation.

FIG. 28 shows the synthetic approach of m-Carborane containing modifier leads to one boron containing group (1A).

FIG. 29 shows the synthetic approach of a Boro-silicate-cage-shaped modifier leads to other boron containing groups (2A) and (2A′).

Table 1 gives the resin properties obtained in Example 2 depend on the loading amount of m-Carborane and RTV-615 hardener.

Table 2 gives the list of the polyorganosiloxane resins synthesized with/without the m-Carborane modifier in Example 3-2.

Table 3 gives the list of the polyorganosiloxane compositions prepared with boron containing material (Trimethyl borate) with/without zirconium containing materials in Example 4.

Scheme 1 shows a general synthetic example of polyorganosiloxanes using hydrosilylation.

Scheme 2 shows the synthetic approach of m-Carborane containing modifier leads to one boron containing group (1A).

Scheme 3 shows the synthetic approach of a Boro-silicate-cage-shaped modifier leads to other boron containing groups (2A) and (2A′).

### DETAILED DESCRIPTION OF THE INVENTION

### <1> Compound (A)

Compound (A) is reacted with the siloxane compound (B) as described later to form the polysiloxane composition according to the present invention.

In this specification, “compound (A)” means a compound having a closed structure, or a compound having a cyclic structure, or a compound having a caged structure and the like are encompassed within this “compound (A)”.

Examples of compound (A), include, but are not limited to, a functional carborane compound, or the compounds represented by the following formulae 2A, 2A′, U, V, W, and W:

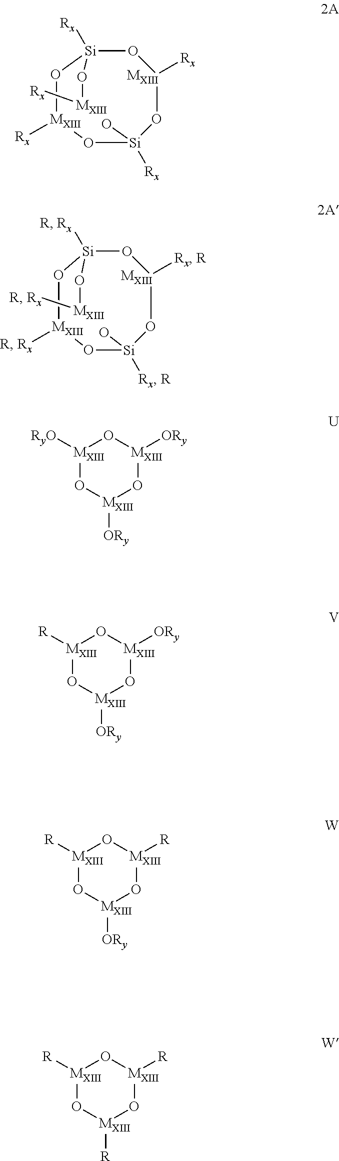

wherein R each independently represents a group selected from hydride, alkyl, alkenyl, aryl, and siloxyl; R_{X} represents an alkenyl or alkynyl group; Ry represents a group selected from hydride, alkyl, alkenyl, and aryl; M_{XIII} represent any 13^{th} group semimetal element of the periodic table, where the three M_{XIII} positions have the same element; and preferably there is 0.1 wt % of the 13^{th} group semimetal element in the polysiloxane composition,

wherein for compound 2A′, the notation ‘R, R_{X}’ indicates that there is either one R or R_{X} at the appropriate locations on 2A′; and there must be at least one R_{X} on 2A′, and the remaining ‘R, R_{X}’ positions can be either R or R_{X}.

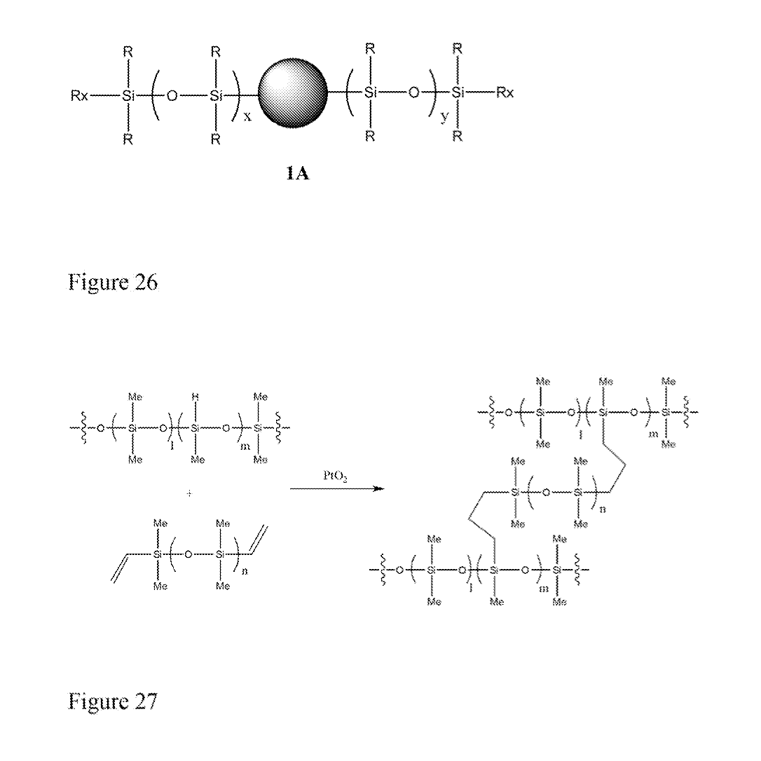

A functional carborane compound-is preferably exemplified by the following structure 1A. (See FIG. 26).

For compound of formula 1A, each R independently represents a group selected from hydride, alkyl, alkenyl, aryl, siloxyl; Rₓ represents an alkenyl or alkynyl group on the molecules; the sphere represents Carborane (B₁₀H₁₀C₂) which can be ortho, meta, or para-Carboranes, and ‘x’ and ‘y’ each are an integer of 0 or more; preferably 0-200 but more preferably 0-50. And preferably, Rx is vinyl.

A functional carborane compound, for example 1A, can be made according to scheme 2, page 28 of the specification. Compounds 2A and 2A′ can be made according to example 1B, on page 30. Compound U is either commercially available or can be synthesized using methods known to those of skill in the art. Compounds V, W and W′ can be synthesized using methods known to those of skill in the art using compound U.

The aforementioned cyclic compounds (A) can be reacted with compound (B) singly or in combination of plural kinds thereof. For instance, compound (B) can be reacted with one or more 1A compounds. Alternatively compound (B) can be reacted with one or more 2A compounds; or compound (B) reacted with one or more 1A compounds plus one or more 2A compounds; etc.

Additives can also be included into the reaction between compound (A) and compound (B). These additives include, but are not limited to, UV stabilizers and thermal stabilizers, commonly known to those of skill in the art. UV stabilizers are commonly added to selectively absorb UV irradiation that would otherwise produce photo-generated radicals that are known to attack the siloxane backbone. The UV stabilizers thereby inhibit the initiating step of photo-degradation of polysiloxane based encapsulants through selective adsorption of UV irradiation. UV stabilizers can be chosen based on the intended wavelength range. Similarly, thermal stabilizers can be added to selectively guard against heat generated radicals.

The content of the compound (A) is usually 0.1 wt % or more, preferably 0.5 wt % or more, and more preferably 1 wt % or more, based on the polysiloxane composition. In addition, the content is usually 80 wt % or less, preferably 50 wt % or less, and more preferably 10 wt % or less. When the content of the compound (A) is too low, there is a concern that sufficient enhancement of a gas barrier ability or sufficient hardness may not be attained. On the other hand, when it is too high, the tuning of the physical properties of the materials becomes difficult.

### <2> Siloxane Compound (B)

The siloxane compound (B) is reacted with the above-mentioned compound (A) to form the polysiloxane composition according to the present invention. Therefore, it is necessary that the siloxane compound (B) has a substituent to be reacted with the above-mentioned compound (A).

For the siloxane compound (B), any one of monomers, oligomers, and polymers can be used, but oligomers or polymers are preferably used for the following reasons.

i) The generation of cracks of a cured product is prevented.

In the case of using a siloxane oligomer or a siloxane polymer, there is less generation of cracks of the polysiloxane composition as a final product formed by curing, as compared with the case of using a siloxane monomer. This is due to a fact that the siloxane oligomer or the siloxane polymer in the polysiloxane composition relieves the internal and external stresses.

ii) Reduction in the weight of the polysiloxane composition which will be problematic during curing by heating is mitigated. Since the siloxane oligomer or polymer has a relatively smaller number of condensable groups contained in the compound than the siloxane monomer, reduction in the weight thereof during curing by heating can be mitigated. As a result, shrinkage of the polysiloxane composition during curing by heating can be relieved. Further, since it is hardly evaporated by heating, the ratio of the 13^{th} group element and Si in the polysiloxane composition as a final product formed by curing can be relatively easily controlled. This means that the curing rate, hardness and the like are relatively easily controlled.

Furthermore, since a chlorosilane-type monomer containing chlorine requires alkaline wash or the like after the reaction, it is not economically desirable.

The siloxane compound (B) may further have a 4^{th} group element in order to improve heat resistance of the polysiloxane composition or impart sufficient hardness to a cured product thereof. As the examples of the siloxane compound (B), for example, the compounds represented by the following formulae A′, A″, B, C, X, Y, and Z′ can be exemplified. These compounds may be used singly or in combination of plural kinds thereof:

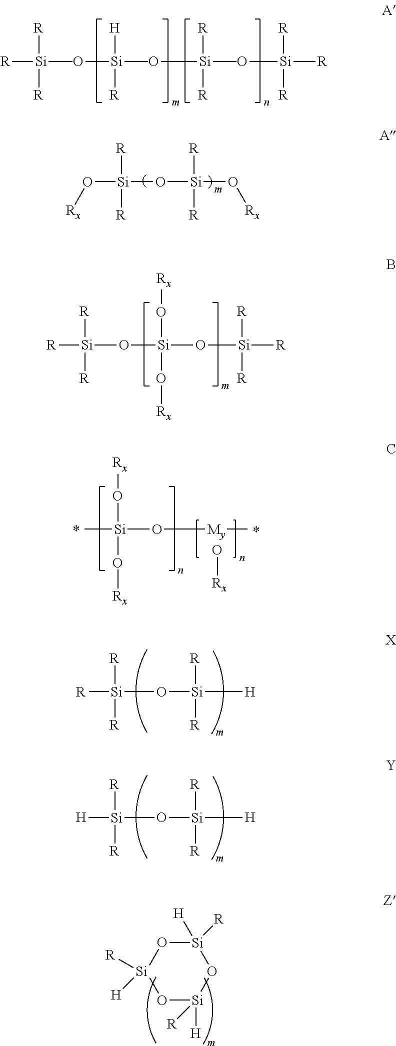

wherein R each independently represents a group selected from hydride, alkyl, alkenyl, aryl, silyl, and a condensable functional group; and as the examples of the condensable functional group, an alkoxyl group and a hydroxyl group are exemplified,

wherein m is an integer of 1 or more; and it is preferably 2,000 or less, and more preferably 1,500 or less,

wherein n is an integer of 0 or more; and it is preferably 2,000 or less, and more preferably 1,500 or less,

wherein O-Rx represents a condensable hydroxyl group or alkoxyl group,

wherein My in structure C is a 4^{th} or 13^{th} group element of the periodic table.

The alkyl, alkenyl, aryl, and silyl group may be substituted with a halogen atom. Examples of the preferred alkyl include methyl, ethyl, propyl and trifluoropropyl. An example of the preferred alkenyl includes vinyl. An example of the preferred aryl includes phenyl. An example of a preferred silyl group includes trimethylsilyl, triethylsilyl, triphenylsilyl, trimethoxysilyl, triethoxysilyl, and triphenoxysilyl groups.

Examples of the above compound (B) can be one commercially available. Specific examples of these include HMS Series, DMS Series, HES Series, HDP Series, HPM Series and HAM Series, products of Gelest, Inc.: and KF-99 and KF-9901, products of Shin-Etsu Chemical Co., Ltd.

The aforementioned siloxane compounds (B) may be used singly or in combination of plural kinds thereof.

The content of the siloxane compound (B) is usually 20 wt % or more, preferably 50 wt % or more, and more preferably 90 wt % or more, based on the polysiloxane composition. Further, it is usually 99.9 wt % or less, preferably 99.5 wt % or less, and more preferably 99 wt % or less. When the content of the siloxane compound (B) is too low, the tuning of the physical properties of the material becomes difficult. On the other hand, when it is too high, there is a concern that sufficient enhancement of a gas barrier ability or sufficient hardness may not be attained.

### <3> Other Additives

Since the polysiloxane composition used in the present invention improves the reaction rate or a cured product thereof has sufficient hardness, the following compounds may be used in addition to the compound (A) and siloxane compound (B) as described above.

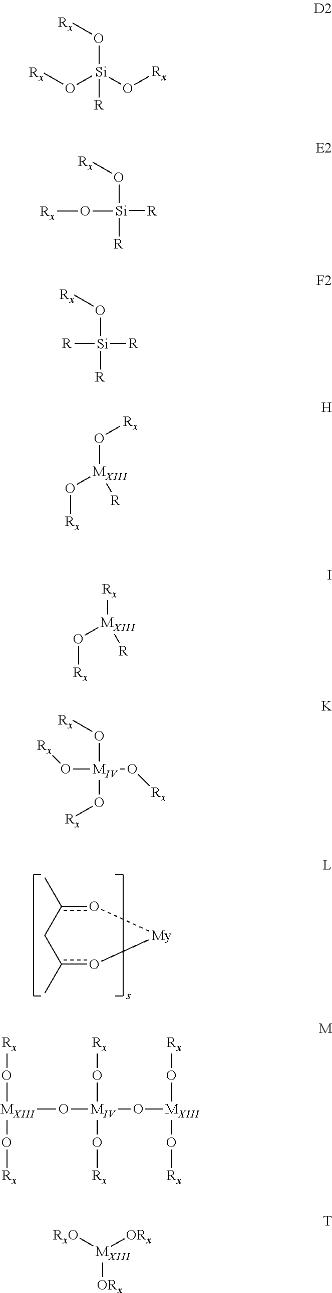

Wherein R each independently represent a group selected from hydride, alkyl, alkenyl, aryl, and siloxyl groups (at least one R is alkyl, alkenyl, or aryl); O-Rx represents condensable hydroxyl and alkoxyl groups; My in L represents a 4^{th} or 13^{th} group element of the periodic table and ‘s’ is 3 when My is a 13^{th} group element, and 4 when My is a 4^{th} group element; M_{XIII} in H, I, M and T represents any 13^{th} group element of the periodic table; M_{IV} in K and M represents any group 4^{th} element of the periodic table; for M, the two M_{XIII} positions have the same 13^{th} group element; and preferably there is at least 0.1 wt % of the 4^{th} or 13^{th} group element or a combination of elements in cross-linked polysiloxane composition.

The content of the above compound is usually 0 wt % or more, preferably 0.05 wt % or more, and more preferably 0.1 wt % or more, based on the polysiloxane composition. Further, it is usually 50 wt % or less, preferably 10 wt % or less, and more preferably 5 wt % or less. When the content of the above compound is too low, a desired effect cannot be exhibited. On the other hand, when it is too high, the tuning of the physical properties of the material becomes difficult.

Furthermore, in addition to the above compounds, various kinds of crosslinkable silane coupling agents may be contained. The total amount of the crosslinkable silane coupling agent is usually 0 wt % or more, preferably 0.05 wt % or more, and more preferably 0.1 wt % or more, based on the polysiloxane composition. Further, it is usually 10 wt % or less, preferably 5 wt % or less, and more preferably 1 wt % or less. When the content of the above compound is too low, a desired effect cannot be exhibited. On the other hand, when it is too high, reduction in the weight due to the evaporation increases, and thus it becomes difficult to control the physical properties of the materials. In addition, it is not economically desirable from an industrial viewpoint since the silane coupling agent is usually expensive.

The polysiloxane compositions may be used as they are (alone), or may be used together with other materials such as solvents, adhesion promoters (e.g. epoxy containing material), and/or filler-like materials (e.g. ceramics particles, metal/metal oxide particles, oxide particles, polymeric particles, and fumed oxides particles, silica-gel, clay, talc, fumed silica and/or fumed alumina) known to those of skill in the art.

Curing of the polysiloxane compositions can occur either by heating at a temperature below 300° C.; more preferably below 180° C.; and even more preferably between the range of 80° C. to 180° C. The curing is not effected by exposure to atmospheric moisture and does not require dry conditions. Alternatively, such curable polysiloxane compositions can be cured by methods known to those of skill in the art such as, but not limited to, using UV radiation or heat.

Further, the semiconductor light emitting device comprising the polysiloxane composition of the present invention can be used with a shape, a transparency or the like that may be appropriately determined depending on the applications, or can be used with mixing with other compounds such as phosphor and inorganic particles.

For example, in the case where the polysiloxane composition of the present invention is used as an encapsulant, it can also be suitably employed for use in specific applications by incorporating phosphor particles or inorganic particles. Specifically, the phosphor is dispersed before the above polysiloxane composition is cured, and then they are molded into a cup of the semiconductor light emitting device as described later, or are applied in the form of a thin layer on a suitable transparent support so as to be used as a member for wavelength conversion. Further, the phosphor may be used singly or in any combination at any ratio of two or more kinds thereof.

The content ratio of the phosphor in the polysiloxane composition of the present invention may be any ratio unless the effect of the present invention is markedly impaired, and it can be arbitrarily selected according to its application form. In the case where a semiconductor light emitting device emitting a white light, which is used for applications such as a white LED and white illumination, is cited as an example, when the phosphor is uniformly dispersed to fill the entire concave portion of a package including the semiconductor light emitting element therewith to perform potting, the total amount of the phosphor is usually 0.1 wt % or more, preferably 1 wt % or more, and more preferably 5 wt % or more, and usually 35 wt % or less, preferably 30 wt % or less, and more preferably 28 wt % or less.

Moreover, in the case where one in which the phosphor is dispersed at a high concentration for the same application is applied in the form of a thin film on a place distant from the light emitting surface of the semiconductor light emitting element in the, semiconductor light emitting device (for example, an opening surface of a package in which a concave section including a semiconductor light emitting element is filled with a transparent encapsulant, a light emitting surface of an external optical member such as a glass cover/lens/light guide plate for LED air-tight encapsulating, and the like), the amount thereof is usually 5 wt % or more, preferably 7 wt % or more, and more preferably 10 wt % or more, and, usually 90 wt % or less, preferably 80 wt % or less, and more preferably 70 wt % or less.

Furthermore, in the case where the polysiloxane composition according to the present invention is used in a semiconductor light emitting device for applications such as encapsulants, package materials, and adhesives (die-bonding materials), inorganic particles may be further contained therein according to the application.

### <4> Method for Producing Polysiloxane Composition

The polysiloxane composition according to the present invention is mainly formed by the reaction of the compound (A) with the siloxane compound (B). As the examples of the reaction, for example, an addition cure system and a condensation reaction can be exemplified.

For example, in the case of using the compound represented by the above formula A′ as the siloxane compound (B), the result of the addition cure system can be a crosslinked structure represented by compound with the structure N.

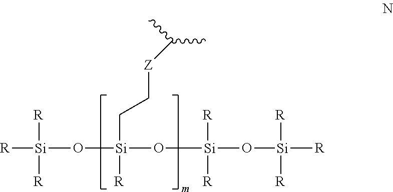

Where Z can represent groups derived from formulae 1A, 2A, 2A′, U, V, W, or W′ after the hydrosilylation reaction.

The amount of Z is based on the number of hydrides from compound A′. R represents a group selected from hydride, alkyl, alkenyl, aryl, siloxyl, and condensable group like hydroxyl, alkoxyl. Compound N can be used as a precursor for further reactions with other compounds with formulas, such as but not limited to D2, E2, F2, H, I, K, L, M and T (above mentioned) to obtain a crosslinked structure.

In another embodiment, cross-linked polysiloxane compositions or composition precursors can be obtained by condensation reactions involving compounds containing hydroxyl, or alkoxyl groups, represented in compounds with formulas such as, but not limited to A′, A″, B, C, X, Y, or Z′ (above mentioned).

The above compounds of formulas A″, B, or C can be cross linked either with themselves (i.e., A″ with A″; or B with B; or C with C). And all of A′, A″, B, C, X, Y, or Z′ can be cross linked with other compounds of formulas such as, but not limited to, D2, E2, F2, H, I, K, L, M and T (above mentioned).

The compounds containing hydroxyl, or alkoxyl groups for the condensation reactions are not limited to above mentioned A″, B, or C. As the alkoxyl groups containing compound for example, Dimethyldimethoxysilane, Dimethyldiethoxysilane, Diphenyldimethoxysilane, Diphenyldiethoxysilane, Vinyl trimethoxysilane, Vinyl triethoxysilane, Vinyl triacethoxysilane, γ-Aminopropyl trimethoxysilane, γ-Glycidoxypropyl trimethoxysilane, γ-Glycidoxypropyl triethoxysilane, β-(3,4-Epoxy cyclohexyl)ethyltrimethoxysilane, γ-(3,4-Epoxy cyclohexyl)ethyltriethoxysilane, γ-Methacryloxypropyl trimethoxysilane, Phenyl trimethoxysilane, Phenyl triacethoxysilane, γ-Mercaptopropyl trimethoxysilane, γ-Chloropropyl trimethoxysilane, β-Cyanoethyl triethoxysilane, Methyltrimethoxysilane, Methyltriethoxysilane, Methyltripropoxysilane, Methyltributoxysilane, Ethyltrimethoxysilane, Ethyltriethoxysilane, Tetramethoxysilane, Tetraethoxysilane, Tetrapropoxysilane, Tetrabutoxysilane, Dimethyldichlorosilane, Diphenyldichlorosilane, Methylphenyl dimethoxysilane, Trimethylmethoxysilane, Trimethylethoxysilane, Trimethylchlorosilane, Methyltrichlorosilane, γ-Aminopropyl triethoxysilane, 4-Aminobutyl triethoxysilane, p-Aminophenyl trimethoxysilane, N-(2-Aminoethyl)-3-aminopropyl trimethoxysilane, Aminoethyl aminomethylphenethyl trimethoxysilane, 3-Glycidoxypropyl trimethoxysilane, 2-(3,4-Epoxy cyclohexyl)ethyltrimethoxysilane, 3-Aminopropyl trimethoxysilane, 3-Aminopropyl triethoxysilane, 4-Aminobutyl triethoxysilane, N-(6-Aminohexyl)aminopropyl trimethoxysilane, 3-Chloropropyl trimethoxysilane, 3-Chloropropyltrichlorosilane, (p-Chloromethyl)phenyltrimethoxysilane, 4-Chlorophenyl trimethoxysilane, 3-Methacryloxypropyl trimethoxysilane, 3-Methacryloxypropyl triethoxysilane, 3-Acryloxypropyl trimethoxysilane, Styrylethyl trimethoxysilane, 3-Mercaptopropyl trimethoxysilane, Vinyl trichlorosilane, Vinyl tris(2-methoxyethoxy)silane, Trifluoropropyl trimethoxysilane can be used preferably.

Also as the alkoxyl group-containing oligomers, KC-89S, KR-500, X-40-9225, X-40-9246 and X-40-9250, KR-217, KR-9218, KR-213, KR-510, X-40-9227 and X-40-9247 from Shin-Etsu Chemical Co., Ltd.: PSI series from Gelest Inc. can be used preferably, too.

As for the hydroxy group-containing compound for example, XC96-723, XF3905, YF3057, YF3800, YF3802, YF3807, YF3897, YF3804, from Momentive Performance Materials, inc.: X-22-4272, X-22-6266, X-21-5841, KF-9701, and KF-353 from Shin-Etsu Chemical Co., Ltd. can be used preferably. Alternatively, Gelest Inc.'s DMS-S12, DMS-S14, PDS-1615, PDS-9931 can be used preferably, as well.

In a preferred embodiment of the invention, the curable polysiloxane compositions can be obtained by hydrosilylation and/or condensation reactions. In case of hydrosilylation reaction the catalyst can be removed after reaction or the catalyst can be present in the final cured composite. It is more preferable to have catalyst removed from the final cured product.

In another embodiment, curable polysiloxane compositions are obtained by hydrosilation, and then cured by condensation. In yet another embodiment, curable polysiloxane compositions are obtained by condensation, and then cured by hydrosilation.

In a preferred embodiment of the invention, the curable polysiloxane compositions can be obtained with either hydrosilylation reactions using a noble metal oxide as a catalyst such as platinum, palladium, gold, osmium or ruthenium oxides. In the case of hydrosilylation, use of solid metal noble catalysts as the reaction catalyst is preferable, too. Since they can be easily removed from the reaction products, and substantially less catalyst residue is present in the curable polysiloxane composition compared to when using conventional methods that rely on fixed supported catalyst, undesirable side-reactions, originating from the presence of such catalyst residue, are reduced. This contributes to markedly improved stability of a polysiloxane product.

It has been further found that a noble metal oxide catalyst separately recovered can be reused, which is a preferred system industrially and economically.

In case of condensation reaction a dehydrating catalysts such as, but not limited to Zr(acac)₄, Al(acac)₃, and Tin octanoate can be used.

In one embodiment, a curable composition comprised of the curable polysiloxane compositions may contain other additives mentioned the section <3>.

As a result of extensive and intensive investigations, it has been found that a polysiloxane composition which includes some amount of the 4^{th} and/or 13^{th} group elements of the periodic table or combinations of both can satisfy the above objects. Such additives were found to enhance the heat and UV durability of the silicones and increase their adhesiveness toward the surface of LED packages, metallic, ceramics, and specifically polymeric packages. As indicated above, the polysiloxane composition in this invention can be produced by taking advantage of hydrosilylation, condensation reactions and/or any other chemical reactions known.

Among condensation reactions, the most preferable reactions are between metal alkoxides of the 4^{th} and 13^{th} groups, and hydrosilyl, alkoxysilyl, and hydroxysilyl groups.

For curing, any reaction mechanism above mentioned can be used as well as equilibrium reaction which includes detachment and reconstruction of Si—O bond and/or Si—C bonds at high temperature with/without catalyst.

The invention also allows for the mechanical properties of the elastomeric resins to be varied and/or tuned to the desired stiffness, toughness and flexibility that best suit the specific application. The system offers a range of material platforms that fulfill all of the requirements and function as advanced encapsulating materials for both LED devices, as well as other emerging applications.

### <5> Embodiment of Semiconductor Light Emitting Device

Hereinbelow, embodiments of the semiconductor light emitting device of the present invention will be described. In each of the following embodiments, the semiconductor light emitting device of the present invention may be simply referred to as a “light emitting device” in some cases.

Further, the polysiloxane composition used in the semiconductor light emitting device of the present invention is referred to as a silicone member. Also, a site at which the silicone member is used will be described all at once after the description of all embodiments. However, these embodiments are only intended to serve for the convenience of description, and examples of the semiconductor light emitting device comprising at least the silicone member are not limited to these embodiments.

### <5-1> Embodiment 1

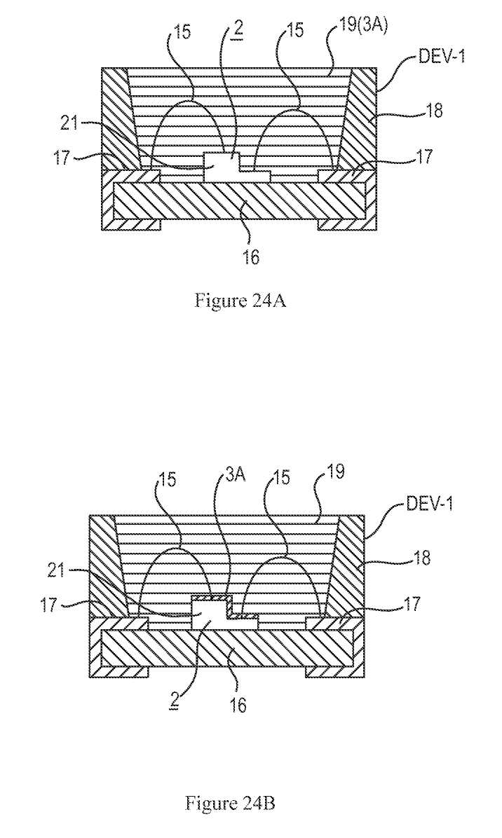

In a light emitting device DEV-1 of the present embodiment, a light emitting element 2 is surface-mounted on an insulated substrate 16 to which a printed wiring 17 is provided, as illustrated in FIG. 24. In this light emitting element 2, a p-type semiconductor layer (not shown) and n-type semiconductor layer (not shown) of the light emitting part 21 are each electrically connected to each of the printed wirings 17, 17 via each of the conductive wires 15, 15. Further, as each of the conductive wires 15, 15, one having a small cross-sectional area is used in order not to interfere with the light emitted from the light emitting element 2.

Herein, as the light emitting element 2, one emitting light at any wavelength in a range from ultraviolet region to infrared region may be used, but a gallium nitride-based LED chip is used herein. Further, in this light emitting element 2, an n-type semiconductor layer (not shown) is formed on the lower side in FIG. 24 and a p-type semiconductor layer (not shown) is formed on the upper side in FIG. 24. Here, since the output light is extracted from the side of the p-type semiconductor layer, explanation will be described with taking the upward portion of FIG. 24 as a front portion.

Furthermore, a frame material 18 having a frame shape, which surrounds the light emitting element 2, is fixed on the insulated substrate 16. The frame material 18 and the insulated substrate 16 may be integrated to constitute a package. An encapsulating part 19 which encapsulates and protects the light emitting element 2 is provided inside the frame material 18. The encapsulating part 19 is formed with a member for the semiconductor light emitting device according to the present invention, and it can be formed by potting with a polysiloxane composition of the present invention. The encapsulating part 19 may contain a phosphor for the purpose of functioning as a member for wavelength conversion of the light emitting element 2.

However, since the light emitting device DEV-1 of the present embodiment comprises the light emitting element 2 and the encapsulating part 19 in which the silicone member according to the present invention is used, optical durability and thermal durability of the light emitting device DEV-1 can be improved. Further, since cracking or peeling do not easily occur in the encapsulating part 19, it is possible to enhance the light transmittance of the light emitting element 2 in the encapsulating part 3A. Further, since the encapsulating part 19 has a high gas barrier property, the light emitting element 2 or the phosphor is hardly deteriorated, and the luminance retention of the light emitting device DEV-1 can be improved.

Furthermore, color blurring or color unevenness can be reduced, as compared with conventional devices, and also, the efficiency for light extraction to the outside can be enhanced. That is, the encapsulating part 19 can be allowed to have high light transmittance to the light emitting element 2 without causing blurring or turbidity, and as a result, uniformity in color appearance is excellent, there is little color unevenness among the light emitting devices DEV-1, and the efficiency for light extraction to the outside of the light emitting element 2 can be increased, as compared with conventional devices. In addition, the weather resistance of the light emitting material can be increased, and an increase in the life time of the light emitting device DEV-1 can be facilitated, as compared with conventional devices.

Further, in the present embodiment, as shown in FIG. 24, the front side of the light emitting element 2 is covered with the silicone member 3A according to the present invention, and also, the encapsulating part 19 formed with materials different from those of the above silicone member 3A is formed on the silicone member 3A. The silicone member 3A is used, for example, in the following applications.

i) A transparent thin film which functions as a light extraction film or encapsulating film on the surface of the light emitting element 2.

ii) A phosphor-containing thin film which functions as a member for wavelength conversion of the light emitting element 2.

The silicone member 3A can be formed, for example, by applying a raw material of the silicone member according to the present invention by means of spin coating or the like when forming a chip of the light emitting element 2. The silicone member 3A is used when needed, and it is a matter of course that the light emitting device of the present invention may be an embodiment which does not have the same.

### <5-2> Embodiment 2

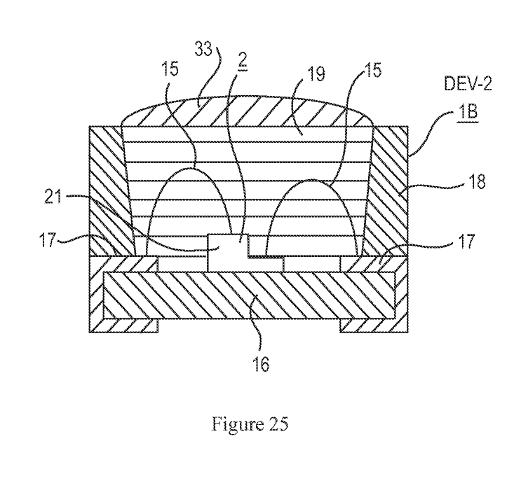

A basic constitution of the light emitting device DEV-2 of the present embodiment is approximately the same as that of Embodiment 1, and as shown in FIG. 25, it is characterized in that a silicone member 33 which is preliminarily formed in the shape of a lens is provided on the upper side of the encapsulating part 19. Also, the components that are the same as in Embodiment 1 are denoted by the same symbols, and their explanations are omitted.

The silicone member 33 is used, for example, in the following applications.

i) A cover for blocking the light emitting device DEV-2 from external oxygen or moisture.

ii) A phosphor-containing optical member, which functions as a member for wavelength conversion of the light emitting element 2.

That is, in i), the upper sides of the light emitting element 2 and the encapsulating part 19 are blocked from external oxygen or moisture by, for example, the silicone member 33 as a transparent cover formed from glass or a highly air-tight resin.

The silicone member 33 and the encapsulating part 19 are directly adjacent to each other and they may have a gap therebetween. However, if they have no gap therebetween, a semiconductor light emitting device having high light extraction efficiency and high luminance can be obtained. In the case where they have a gap therebetween, it is preferable to perform vacuum encapsulation or inert gas enclosure.

In this embodiment, invasion of external factors such as moisture and oxygen, which promote the deterioration of the phosphor/encapsulating resin, or volatilization of a gas decomposing the encapsulating resins by heat/light is inhibited by the silicone member 33, and therefore, there is an advantage that luminance reduction or shrinkage and peeling of the encapsulating part due to the invasion or volatilization can be reduced.

Furthermore, in ii), the silicone member 33 is excited by light derived from the light emitting element 2, thereby emitting light at a desired wavelength. In the case where the encapsulating part 19 is formed of an optical member containing no phosphor, it is desirable in that there is no damage owing to elution of impurities, which is caused by heat generation due to the excitation of the phosphor or deterioration of the phosphor, or the like, as compared with an embodiment in which phosphor is directly contained in the encapsulating part 19.

However, in the light emitting device DEV-2 of the present embodiment, the silicone member 33 has a function for wavelength conversion as well as a function as a lens, and as a result, orientation of light emitted due to the lens effect can be controlled. In the case where at least one effect of the above i) and ii) is expected without expecting the lens effect, the silicone member may not have a lens shape, but may have a surface (upper side) of flat plate shape. Further, in the case where the light extraction effect is expected, the silicone member may be formed so that the surface (upper side) may have a concave-convex shape instead of a lens shape.

In addition, in an embodiment of the light emitting device of the present invention, various types can be applied, and those as described, for example, in paragraphs [0395] to [0512] in the pamphlet of WO 2006/090804 can be used as they are, and also, appropriately design-modified light emitting devices may also be applied.

### <5-3> Application to Member for Semiconductor Light Emitting Device Other than Encapsulant

In the light emitting device (semiconductor light emitting device) of each of Embodiments 1 and 2 as described above, the places to which the silicone member according to the present invention is applied are not particularly limited. In each of the above embodiments, examples in which the silicone member is applied to the members which form the encapsulating part 19 are shown, but in addition, for example, the silicone member can be suitably used as a member which forms the above optical member 3A (FIG. 24), optical member 33 (FIG. 25), frame material 18 (FIGS. 24 and 25), package (FIGS. 24 and 25) in which the frame material 18 and insulated substrate 16 are integrated, and the like. By using the optical member according to the present invention as the members, various effects such as an excellent encapsulating property, transparency, light resistance, heat resistance, film forming property and inhibition of cracking or peeling due to long-term use, as described above, can be attained.

Moreover, since the polysiloxane composition according to the present invention has good adhesiveness as described above, it can be used as an adhesive for semiconductor light emitting device, as well as it can be used in the above-mentioned optical members. Specifically, for example, in the case where a semiconductor element is adhered to a package, the case where a semiconductor element is adhered to a submount, the case where the components of a package are adhered to each other, the case where a semiconductor light emitting device is adhered to an external optical member, and other cases, the polysiloxane cured product of the present invention can be used by applying, printing, potting, or the like. The polysiloxane composition according to the present invention is excellent, particularly in light resistance and heat resistance, and as a result, in the case where it is used as an adhesive for high-output semiconductor light emitting device which is exposed to a high temperature or ultraviolet rays for a long period of time, a semiconductor light emitting device which can be used for a long period of time and has high reliability can be provided.

The light emitting device of the present invention can be used singly or in combination of plural kinds thereof as, for example, back lights for such as an illuminating lamp and a liquid crystal panel, various illuminating devices such as ultrathin illumination, or image display devices.

### <6> Other Applications of Polysiloxane Composition

The polysiloxane composition of the present invention is not limited in the application thereof, but it can be suitably used in various optical members other than an LED since it has superior properties such as light ray transmittance (transparency), light resistance, heat resistance, water and heat resistance, UV resistance and low foaming property. As the specific examples of the applications of the optical member comprising the polysiloxane cured product of the present invention, a light guide plate, a member for application in the space industry, and the like are exemplified.

### <6-1> Light Guide Plate

As an example of the optical member of the present invention comprising at least the polysiloxane composition according to the present invention, a light guide plate (hereinafter suitably referred to as “the light guide plate of the present invention” in some cases) comprising at least the optical member of the present invention will be described.

The curable polysiloxane composition of the present invention can be used as an optical member in optical communication systems, in particular, optical transmitter and receiver modules. In an optical waveguide for transporting an optical signal, high productivity and low cost, as well as various properties such as light ray transmittance (transparency), light resistance, heat resistance, water and heat resistance and UV resistance, are required. Since it has the above-described properties, it is preferably used as a light guide plate which emits light emitted from a light source at a desired position, particularly in optical instruments, for example, when displaying a display part of a display device such as a display, button parts of facsimiles, phones, mobile phones, and other various electrical appliances, or the like. The curable polysiloxane composition of the present invention can attain particularly a high refractive index, and thus, it is suitable as an optical member in a light guide plate, and a so-called core layer (core part) of the optical waveguide.

### <6-2> Member for Application in Space Industry

As an example of the optical member of the present invention, comprising at least the polysiloxane composition of the present invention, a member for application in the space industry will be described. The curable polysiloxane composition of the present invention has excellent various properties such as light ray transmittance (transparency), light resistance, heat resistance, water and heat resistance and UV resistance, and it can be used for materials for application in the space industry requiring the above-described properties. As the materials for application in the space industry, it can be used for, for example, static electricity eliminating materials, conductive adhesives, materials for gaskets, flash defense materials, electromagnetic shielding materials, materials for tanks, external materials for rockets, or the like by making a composite with carbon-based nano materials.

The invention provides semiconductor light emitting devices using specific polysiloxane compositions that can be cured by heat in the presence of the 13^{th} group elements in the periodic table. Polysiloxane compositions produced by the above method have excellent adhesion, transparency, resistance to moist heat and UV resistance, and are therefore useful in various applications such as an encapsulation resin of LED.

The total content of the 13^{th} group elements in the periodic table can be between 0.1 wt % and 80 wt %; 0.5 wt % and 80 wt %; 1.0 wt % and 80 wt %; preferably, between 0.1 wt % and 50 wt %; 0.5 wt % and 50 wt %; 1.0 wt % and 50 wt %; more preferably between 0.1 wt % and 10 wt %; 0.5 wt % and 10 wt %; and 1.0 wt % and 10 wt %. If the content is more than 80 wt %, the tuning of the physical properties of resins become very difficult.

The 4^{th} group (titanium, zirconium, hafnium) or the 13^{th} group (boron, aluminium, gallium, indium, thallium) elements especially boron, aluminum, or zirconium containing material usually has higher refractive index than normal polysiloxanes. And adding such elements in a polysiloxane composition is preferable because they can increase the overall refractive index and lead to higher light extraction when it is used as an encapsulating material of LED.

In another embodiment, the polysiloxane compositions for the semiconductor light emitting devices can be produced by either hydrosilylation or condensation reactions of raw materials possessing average molecular weights of 3,000 or more. In a more specific embodiment, the weight average molecular weight determinations are obtained by measuring with GPC (gel permeation chromatography) using a polystyrene standard material in calibration curve measurement.

Scheme 1 (See FIG. 27) represents one general procedure of the preparation of the silicone-based resin backbone which involves the functionalization/modification of a methylhydrido-polydimethylsiloxane (H-PDMS) using for example hydrosilylation. High molecular weight vinyl silanes are preferably incorporated along the polysiloxane backbone by hydrosilylation using a solid PtO₂ catalyst, for example. Homogeneous catalyst can be used without any problem but solid catalyst is also preferably used and it can be removed simply by centrifugation or filtration after the reaction. This subsequent catalyst-free, PDMS-based liquid resin is unique and different from other conventional PDMS-based resins include homogeneous catalysts. See for example U.S. Pat. No. 7,160,972 B2 that discloses a polysiloxane-based resin typically employing hydrosilylation curing chemistry. Such resin type requires 2-part systems, where part A contains the platinum catalyst together with vinylsiloxane copolymer and part B is the hydridosiloxane copolymer.

And for example in the patent WO 2008/018981 A2 (15), they claim silicone composites including Boron, Aluminum, and/or Titanium. But none of the silicon elements of their backbones have alkyl, alkenyl, alkynyl, or aryl functional group directly attached on Si, the overall material should be physically very hard and/or brittle and they are not suitable for using as an encapsulating material of a LED.

One key point of this invention is simplicity and functionality. The one-pot nature of the formulation can make the system very attractive. Additionally, the catalyst-free system, when solid metal oxide catalysts were applied, eliminates problems that may arise due to unwanted side reactions related to the catalyst residue.

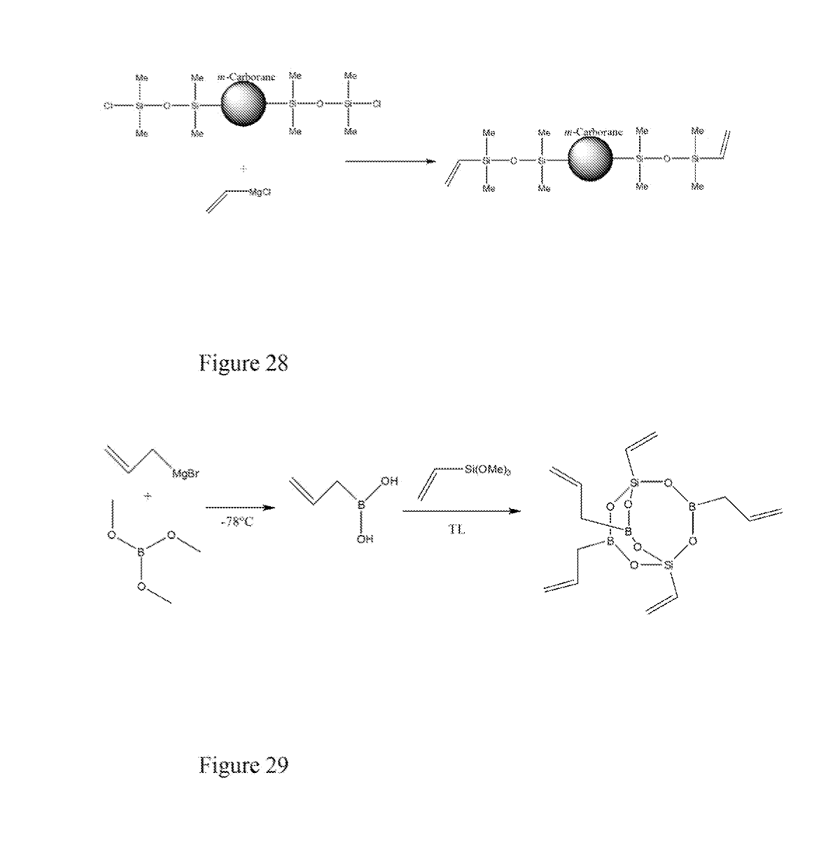

Scheme 2 illustrates the synthetic approach of materials with boron containing group 1A (See FIG. 28). The method is very simple and straightforward as described in the experimental section (16, 17).

Scheme 3 illustrates the synthetic example of cage shaped materials with boron containing groups (See FIG. 29). The synthetic approach is again very straightforward as depicted in the experimental section.

The present invention is described further specifically by the Examples, but it should be understood that the invention is not limited to the following Examples so far as the invention is not beyond its gist.

### EXAMPLES

Hereinafter, in Examples 1 to 3, the polysiloxane compositions used in the present invention were investigated.

### Example 1

Synthesis of the Modifier Containing a Cyclic Compound Containing a 13^{th} Group Element of the Periodic Table

(a) Synthesis of m-Carborane Containing Modifier of the Silicones for the Encapsulant of the Present Invention's Semiconductor Light Emitting Devices

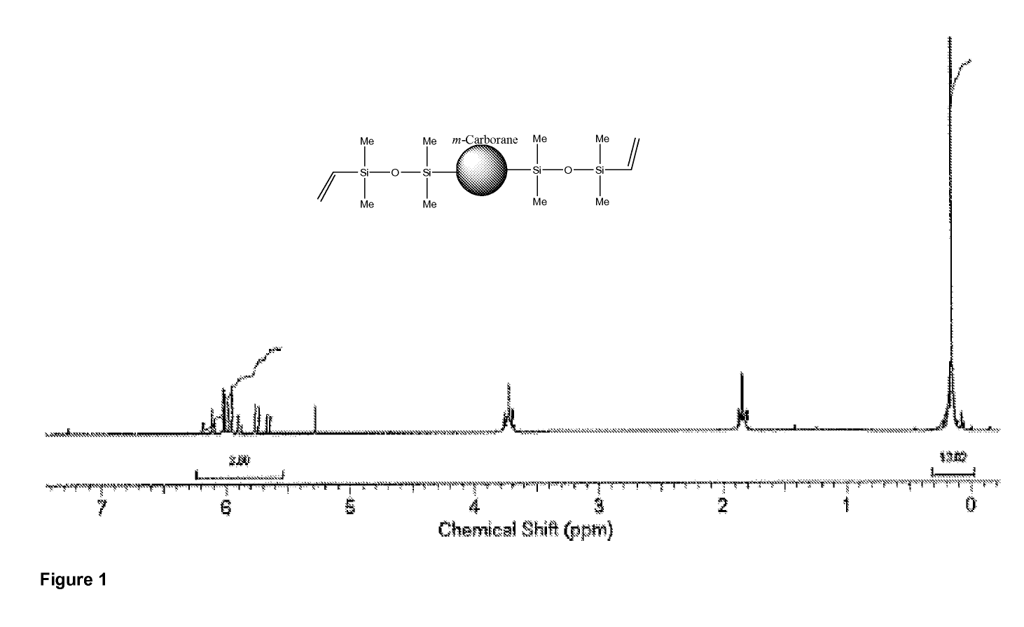

The synthesis of the m-Carborane containing modifier was carried out by the reaction of 1,7-Bis(chlorotetramethyldisiloxlyl)-m-carborane (DEXSIL 300M from DEXSIL Co.) with 1M Vinyl magnesiumbromide (1.3 eq) in anhydrous THF. After the reaction was completed, excess Grignard reagent was neutralized by addition of Methanol. The mixture was then concentrated and the product was extracted into Ethyl acetate which was washed with 1M HClaq. After drying, the product was purified by column chromatography in Hexanes to obtain the m-Carborane cross-linker and the crude product was distilled at 275° C. to obtain a transparent crosslinker. (85% yield) Concentrated HClaq was used as a TLC stain. FIG. 1 shows ¹H-NMR spectrum of this m-Carborane containing modifier. The obtained m-Carborane containing modifier had a refractive index n²⁰_{d} of 1.4873.

### (b) Synthesis of Boro-Silicate-Cage-Shaped Modifier (for Example, 2A and 2A′)

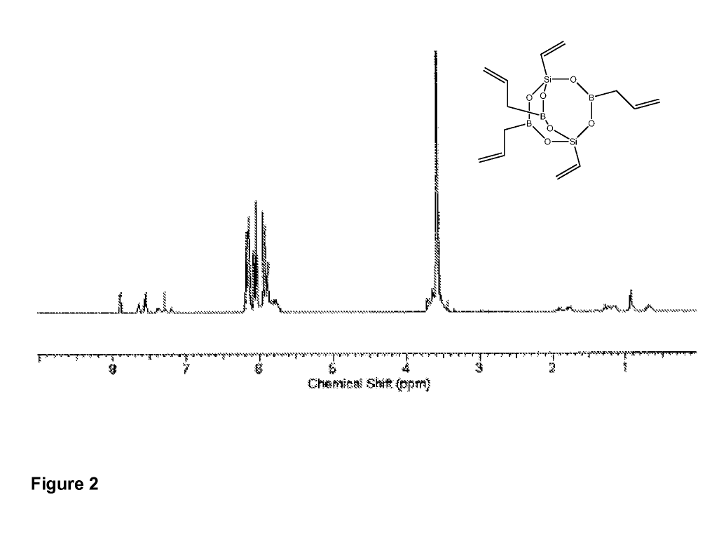

Allyl-boric acid was synthesized by the reaction of Trimethylborate and Allylmagnesium bromide (1.3 eq) in Et₂O at −78° C. The obtained Allyl-boric acid was washed with water and dilute HClaq to remove the inorganic salts. The Allyl-boric acid was then further reacted with Vinyltrimethoxysilane in refluxing Toluene. On removal of Toluene and Methanol, the Boro-silicate-cage-shaped modifier was obtained as colorless film. FIG. 2 shows ¹H-NMR spectrum of this Boro-silicate-cage-shaped modifier.

### Example 2

Functionalization of Commercially Available Polyorganosiloxane with the Modifier having a Cyclic Compound Containing a 13^{th} Group Element of the Periodic Table

m-Carborane containing modifier was added to the commercially available silicone resin RTV-615 (Momentive Performance Materials Inc.) as a drop-in-modifier. By changing the amount of m-Carborane containing modifier as well as the amount of RTV-615 Part B (hardener), the physical properties of the resultant colorless transparent poyorganosiloxane resins was found to be tuned very easily. (See Table 1)

TABLE 1
Resin properties depend on the loading amount of m-Carborane containing
modifier and RTV-615 hardener.

| | | RTV-615 | | | | |
|---|---|---|---|---|---|---|
| | RTV-615 | Part B | Carborane | | | |
| | Part A | (Hardener) | Modifier | | Curing | Physical |
| Entry | (wt %) | (wt %) | (wt %) | Boron content | Codition | Properties |
| 1 | 90 | 10 | 0 | 0 wt % | 120° C. * 1 hr | Tough |
| 2 | 85 | 10 | 5 | 1.2 wt % | 120° C. * 1 hr | Very Soft |
| 3 | 81 | 9 | 10 | 2.4 wt % | 120° C. * 1 hr | Jelly |
| 4 | 71 | 24 | 5 | 1.2 wt % | 120° C. * 1 hr | Tough |
| 5 | 52 | 43 | 5 | 1.2 wt % | 120° C. * 1 hr | Hard tough |
| 6 | 50 | 40 | 10 | 2.4 wt % | 120° C. * 1 hr | Hard tough |

Also it was found that adding m-Carborane containing modifier makes the surface of the cured resin smoother for some reason.

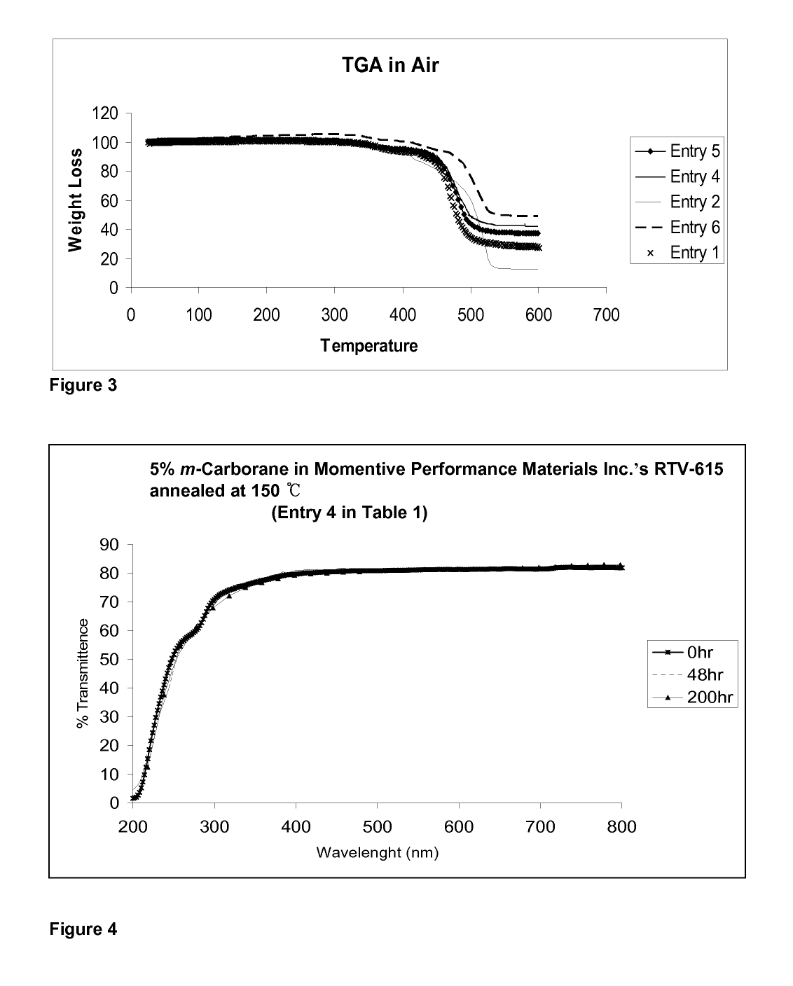

The TGA study of these resins reveals that m-Carborane modified resins give slightly higher char level which means they have higher thermal durability. (See FIG. 3)

Also, the UV-VIS spectrum of the sample from Entry 4 in Table 1 reveals that the resin retains its transparency completely even after 150° C.*200 hr thermal durability test. (See FIG. 4)

### Example 3

Functionalization of Polyorganosiloxane with the Modifier having a Cyclic Compound (1 A) Containing a 13^{th} Group Element of the Periodic Table

### Example 3-1

The preparation reactions of the polyorganosiloxane compositions invented were carried out by mixing hydrosilyl group containing PDMS (Polydimethylsiloxane) (HMS-064 from Gelest Inc.), vinyl containing T-type PDMS (VTT-106 from Gelest Inc.), and m-Carborane containing modifier in Example 1(a), and catalytic amount of PtO₂ in Toluene (50 wt % of the total weight) at 80° C. for 1 hr.

The amount of the reagents was adjusted so that the mole amount of total vinyl group and hydrosilyl group became almost the same.

Three materials were synthesized by changing the amount of the Carborane containing modifier which means 10 wt % (boron content: 2.4 wt %), 15 wt % (boron content: 3.5 wt %), and 20 wt % (boron content: 4.7 wt %).

After the reaction, the residual PtO₂ was removed by passing over Biotage ISOLUTE® Si-Thiol resin and/or by centrifugal separation (6200 rpm*10 min.).

After removal of Toluene by reducing the pressure, the material was either cast in Teflon dishes or in glass vials and heated to cure. The curing completed in 3 to 4 hours at 150° C. in air.

Instead of PtO₂, Karstedt's catalyst diluted by Toluene (final Pt content was 0.4 wt %) could be used as a homogeneous Pt catalyst. In Karstedt's catalyst's case, curing completed within 10 minutes at 150° C.

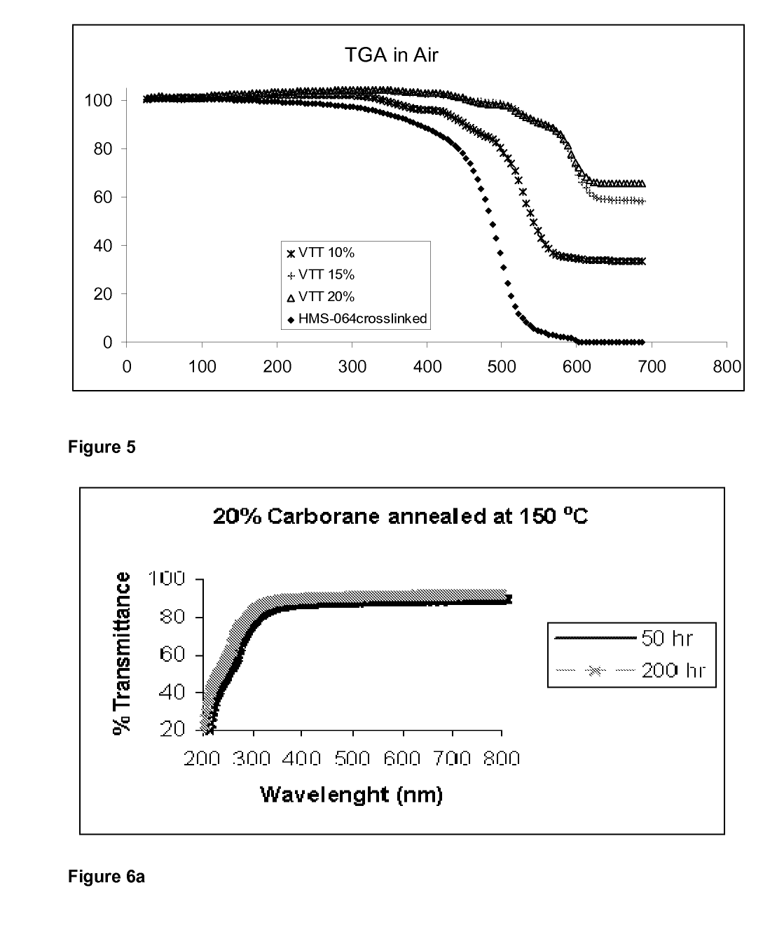

The TGA study of these polyorganosiloxanes synthesized in Example 3-1 together with TGA study of m-Carborane containing raw material, DEXSIL 300GC and hydrosilyl group containing raw material HMS-064 revealed that higher m-Carborane contents give higher thermal durabilities. (See FIG. 5)

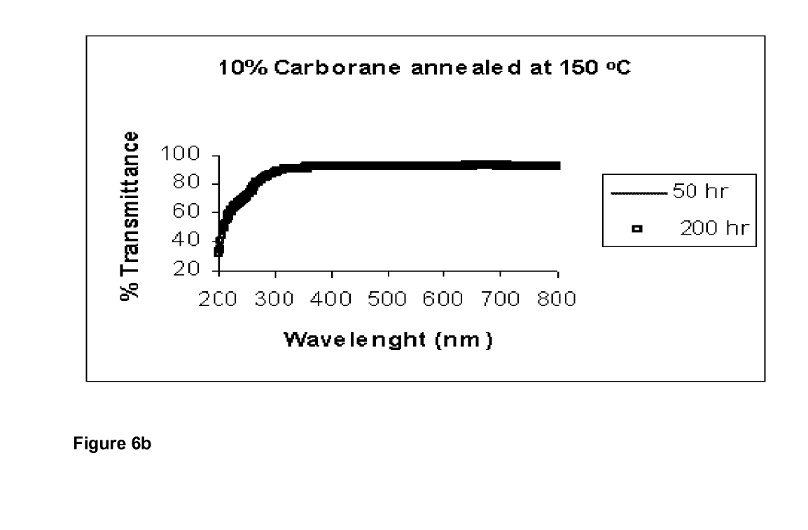

The UV-VIS data for the invented materials (i.e. for example VTT 10% means that the content of m-Carborane was 10 wt % of the total weight of HMS-064, VTT-106, and m-Carborane) showed that there was no change in the spectrum even after annealing for 200 hr at 150° C. (See FIG. 6a and FIG. 6b).

### Example 3-2

Another preparation reaction of the polyorganosiloxane compositions invented was carried out by mixing hydrosilyl group containing PDMS (KF-9901 from Shin-Etsu Chemical Co.), both end vinyl group terminated linear PDMS (ME-91 from Momentive Performance Materials Inc.), and m-Carborane containing modifier in Example 1(a), and catalytic amount of PtO₂ at 80° C. for 1 hr.

Two materials were synthesized with/without the m-Carborane containing modifier. (Entry 7 and 8 in Table 2)

After the reaction, the residual PtO₂ was removed by centrifugal separation (6200 rpm*10 min.).

TABLE 2
Polyorganosiloxane resins synthesized with/without the m-Carborane
containing modifier.

| | | | | | | | Hardness of | Cured |
|---|---|---|---|---|---|---|---|---|
| | | | | Carborane | | | the Cured | Sample's |
| | Targeted Si-=/Si—H | KF-9901 | ME-91 | Modifier | Boron | | Sample | Refractive |
| Entry | (Mole Ratio) | (wt %) | (wt %) | (wt %) | content | Curing Codition | (JIS Type A) | Index (n²⁰_{d}) |
| 7 | 100/100 | 7 | 83 | 10 | 2.4 wt % | 150° C. * 3 hr + | 17 | 1.4108 |
| | | | | | | 170° C. * 2 hr | | |
| 8 | 8/100 | 7 | 93 | 0 | 0 wt % | 150° C. * 3 hr + | 16 | 1.4069 |
| | | | | | | 170° C. * 2 hr | | |

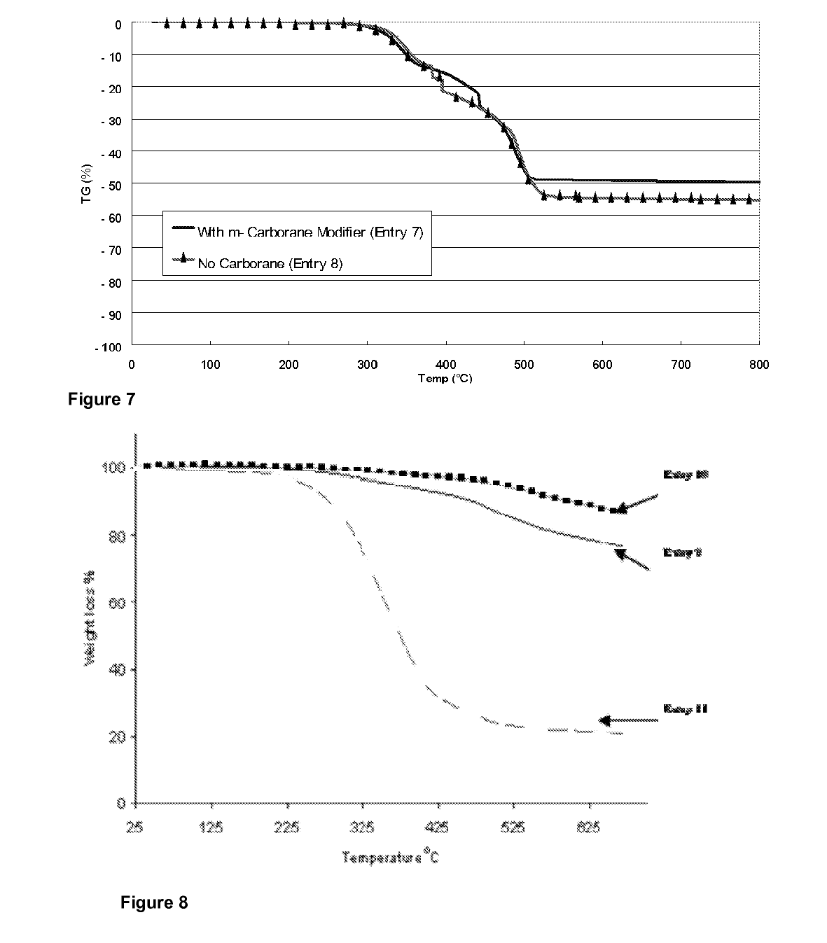

The TGA study (10° C./min. in air) of these polyorganosiloxanes synthesized in Example 3-2 revealed that higher carborane contents again gave higher thermal durabilities. FIG. 7 shows TGA data of resins with/without m-Carborane containing modifier.

### Example 4

Functionalization of Polyorganosiloxane with the Modifier having a Cyclic Compound (U) Containing a 13^{th} Group Element of the Periodic Table

### Example 4-1

5 g of polydimethyl siloxane modified with hydroxyl groups at both terminals (YF3800, manufactured by Momentive Performance Materials Inc.) and 0.25 g of trimethoxyboroxin (manufactured by Tokyo Chemical Industry Co., Ltd.) were added to a 20-ml screw tube, followed by stirring at room temperature for 3 hours. Then 2 g of the reaction product was placed on a PTFE petri dish, followed by heating in a ventilation heater at 150° C. for 3 hours. As a result, a cured product thereof was obtained, and the Shore A hardness thereof was measured by means of an ASKER Durometer Type AL, which was found to be 26. In addition, the weight retention rate between before and after curing by heating was 95.6%.

### Comparative Example 4-1

The same operation as in Example 4-1 except that the boron compound was changed to trimethoxyborane was carried out. The hardness of the obtained cured product was measured, and as a result, the Shore A hardness was found to be 14 and the weight retention rate between before and after curing by heating was 94.8%.

### Comparative Example 4-2

The same operation as in Example 4-1 except that the boron compound was changed to triisopropyl borate was carried out. The hardness of the obtained cured product was measured, and as a result, the Shore A hardness was found to be 15 and the weight retention rate between before and after curing by heating was 93.9%.

### Example 5

Functionalization of Polyorganosiloxane with the Modifier having a Cyclic Compound (U) Containing a 13^{th} Group Element of the Periodic Table

### Example 5-1

The same operation as in Example 4-1 except that 0.0306 g of Nikka Octhix (a zirconium-containing catalyst mineral spirit solution manufactured by NIHON KAGAKU SANGYO CO., LTD.) as a catalyst component was added. The Shore A hardness of the obtained cured product was measured, and as a result, it was found to be 23. Further, the weight retention rate between before and after curing by heating was 95.0%.

### Comparative Example 5-1

The same operation as in Example 5-1 except that the boron compound was changed to trimethoxyborane was carried out. The hardness of the obtained cured product was measured, and as a result, the Shore A hardness was found to be 18 and the weight retention rate between before and after curing by heating was 93.6%.

### Comparative Example 5-2

The same operation as in Example 5-1 except that the boron compound was changed to triisopropyl borate was carried out. The hardness of the obtained cured product was measured, and as a result, the Shore A hardness was found to be 15 and the weight retention rate between before and after curing by heating was 93.0%.

### Example 6

Functionalization of Polyorganosiloxane with the Modifier having a Cyclic Compound (U) Containing a 13^{th} Group Element of the Periodic Table

### Example 6-1

2 g of side-chain hydrosilylsiloxane (HMS-071, manufactured by Gelest Co., Inc.), 0.25 g of trimethoxyboroxin (manufactured by Tokyo Chemical Industry Co., Ltd.), and 0.0341 g of a 1 wt % toluene solution of tris(pentafluorophenyl)borane (manufactured by Aldrich) were added to a 20-ml screw tube, followed by stirring at. room temperature for 3 hours. Then, 2 g of the reaction product was placed on a PTFE petri dish, followed by heating in a ventilation heater at 150° C. for 3 hours. As a result, a cured product which was transparent and flexible was obtained. In addition, the weight retention rate between before and after curing by heating was 88.8%.

### Comparative Example 6-1

The same operation as in Example 6-1 except that the boron compound was changed to 0.25 g of trimethoxyborane (manufactured by Wako Pure Chemical Industries, Ltd.) was carried out. As a result, curing was not attained at all under heating at 150° C. for 3 hours. In addition, the weight retention rate between before and after curing by heating was 88.1%.

Hereinbelow, in Examples 7 to 11, Reference Examples for the compound with the 4^{th} or 13^{th} group element or a combination of elements, which may be additionally used in the polysiloxane of the present invention, are shown.

### Example 7

Preparation of Polyorganosiloxane Compositions with Boron Containing Materials as well as Zirconium Containing Materials

Polyorganosiloxane compositions were prepared by using condensation reactions of hydroxysilyl groups and alkoxysilyl group in the presence of boron containing materials and zirconium containing materials.

The zirconium containing materials served as a catalyst of the reaction as well as a reagent.

1.0 g of Trimethoxyvinylsilane, 1.0 g of Trimetyl borate, 1.5 g of both end hydroxyl group terminated PDMS (Gelest Inc.'s DMS-S12), and zirconium containing materials were mixed and heated up to 150° C. for 1 hr. (Entry 11 is without zirconium.)

TABLE 3
Polyorganosiloxane compositions prepared with boron containing material
(Trimethyl borate) with/without zirconium containing materials.

| | | | | | | Total | | |
|---|---|---|---|---|---|---|---|---|
| | | | | | | content | | |
| | Trimethoxy | | Trimethyl | | | of boron | | |
| | vinylsilane | DMS-S12 | borate | Zr(acac)₄ | Zr(n-BuO)₄ | and | Curing | Physical |
| Entry | (wt %) | (wt %) | (wt %) | (wt %) | (wt %) | zirconium | Codition | Properties |
| 9 | 28 | 41 | 28 | 3 | — | 3.4 wt % | 150° C. * 1 hr | Transparent |
| | | | | | | | | elastomer |
| 10 | 28 | 41 | 28 | — | 3 | 3.7 wt % | 150° C. * 1 hr | Slightly hazy |
| | | | | | | | | elastomer |
| 11 | 29 | 42 | 29 | — | — | 3.0 wt % | 150° C. * 1 hr | Hazy soft |
| | | | | | | | | elastomer |

The TGA study of the polyorganosiloxane compositions prepared in Example 7 revealed that higher boron and zirconium contents gave higher thermal durabilities. (FIG. 8)

### Example 8

Synthesis of Zirconium-Containing Polysiloxane Using Aluminum Zirconium Double Metal Alkoxide:

To a 20 mL scintillation vial with a stir bar was added 4 g of silanol terminated poly(dimethylsiloxane) (Gelest Inc.'s DMS-S12), 0.4 g of Diethoxysiloxane-s-butylaluminate copolymer (Gelest Inc.'s PSIAL-007), and 0.4 g of Aluminum zirconium double metal alkoxide (Gelest Inc.'s DALZR50, 0.67M). Reaction mixture was stirred in an oil bath at 65° C. for 1.5 hr and placed in a vacuum oven at 40° C. for 24 hr, at which point it still remained a transparent liquid. The liquid was cast in a Teflon dish and placed in an oven at 150° C., where it cured after 3.5 hr and was found to have 15% loss of weight, and after the curing, there observed negligible weight loss even after 48 hour annealing at 150° C.

### Example 9

Synthesis of Zirconium-Containing Polysiloxane Using Zirconium n-butoxide:

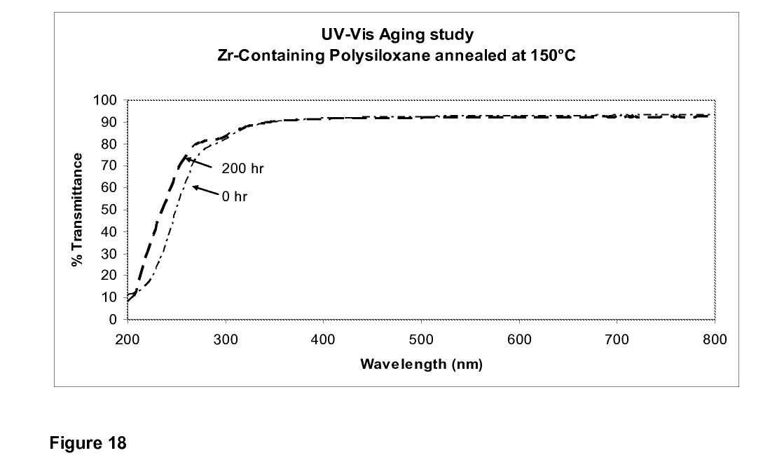

Same synthetic method as Example 8 above but replacing 0.4 g of Aluminum zirconium double metal alkoxide with 0.2 g of Zirconium n-butoxide. See FIG. 18 for the UV-Vis spectra of the cured product of this reaction.

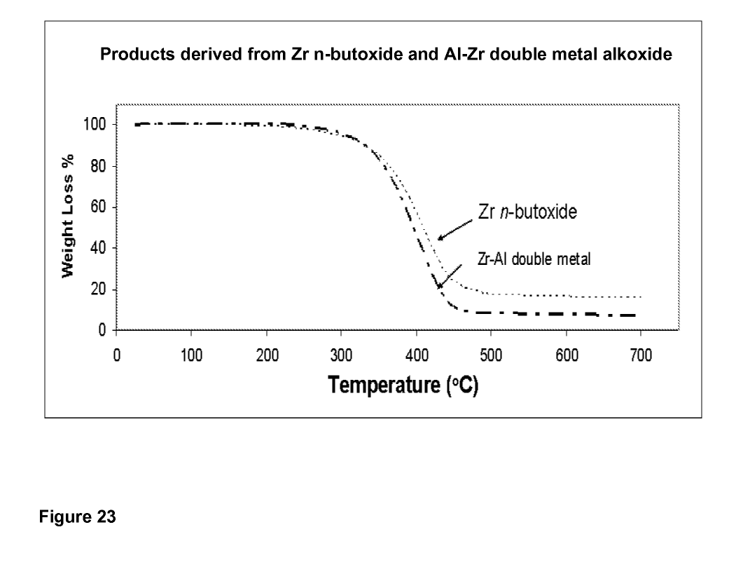

The thermogravamatric analysis (TGA) data also revealed heat stability of the samples obtained in Example 8 and 9 up to 350° C. (FIG. 23)

### Example 10

Synthesis of Siloxane Aluminate:

To a 20 mL scintillation vial with a stir bar was added silonal terminated poly(dimethylsiloxane) (Gelest Inc.'s DMS-S12, DMS-S15, or DMS-S33) and Vinyltrimethoxysilane (Gelest Inc.'s SIV9250.0) in Toluene (50 wt %). The reaction mixture was stirred uncovered in an oil bath at 70° C. for 1 hr at which point Diethoxysiloxane-s-butylaluminate copolymer (Gelest Inc.'s PSIAL-007) was added and stirred overnight at room temperature. Solvents were removed underreduced pressure and placed in a vacuum oven at 40° C. for 1 hr at which point it still remained a transparent liquid. The liquid was then placed in an oven at 150° C., where it cured overnight.

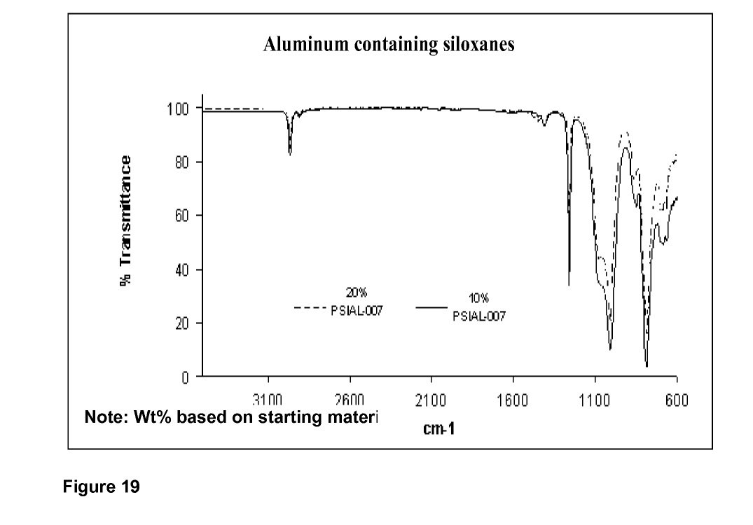

The FTIR spectrum shows the completed reaction and NO OH peaks were between 3200 and 3550 cm⁻¹ observed (FIG. 19)

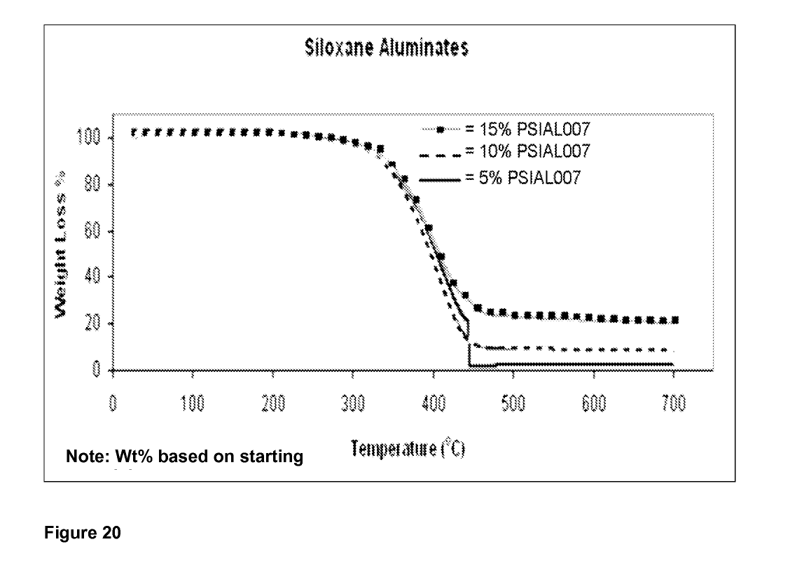

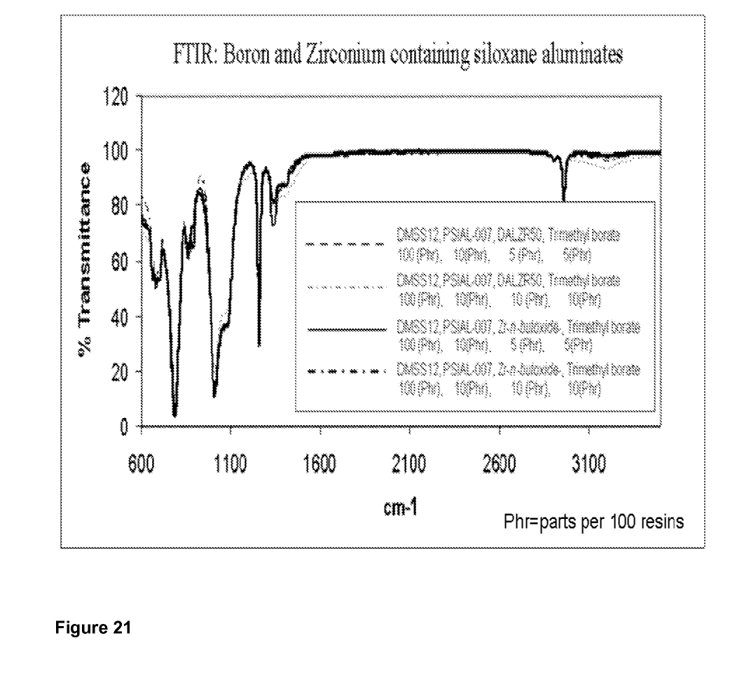

The siloxane aluminate shows its high thermal stability up to 350° C. (FIG. 20)

### Example 11

Synthesis of Boron and Zirconium Containg Siloxane Aluminate:

To a 20 mL scintillation vial with a stir bar was added silonal terminated poly(dimethylsiloxane) (Gelest Inc.'s DMS-S12) and Aluminum zirconium double metal alkoxide (Gelest Inc.'s DALZR50, 0.67M) or Zirconium n-butoxide (Gelest Inc.'s AKZ945). The reaction mixture was stirred for 1 minute, after which Trimethyl borate and Diethoxysiloxane-s-butylaluminate copolymer (Gelest Inc.'s PSIAL-007) were added. Then the reaction mixture was stirred in an oil bath at 65° C. for 1.5 hr and placed in a vacuum oven at 40° C. for 24 hr, at which point it had already cured. The cured material was further placed in an oven at 150° C. overnight.

Overlaid FTIR spectra in FIG. 21 are those of the samples prepared in this Experiment 11 containing Gelest Inc.'s DMS-S12, Diethoxysiloxane-s-butylaluminate copolymer (Gelest Inc.'s PSIAL-007), Al/Zr double metal alkoxide, Zirconium n-butoxide, and Trimethylborate in different concentrations. It was found that Al/Zr double metal alkoxide reaction (DALZR50) goes to completion when compared to

Zirconium n-butoxide since in the former case, a very small or no OH peak was detected between 3200 and 3550 cm⁻¹.

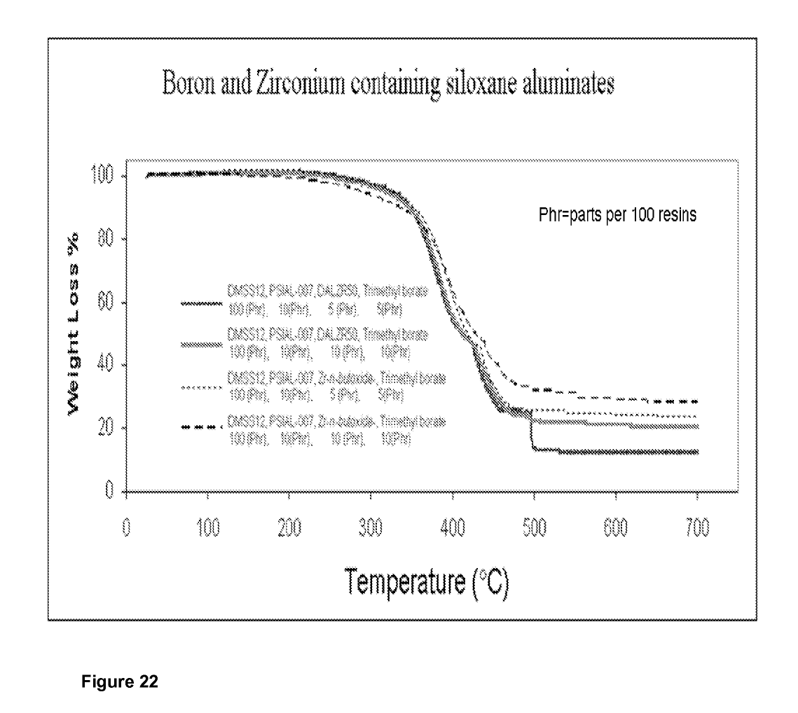

The TGA data show all the mixed boron, zirconium siloxane aluminate materials obtained in Example 11 are stable up to 350° C. (FIG. 22).

### Evaluation Examples

Performances of the Polyorganosiloxane Compositions Obtained in the Example 3-2 were Evaluated.

### (Hydro)Thermal Durability Test

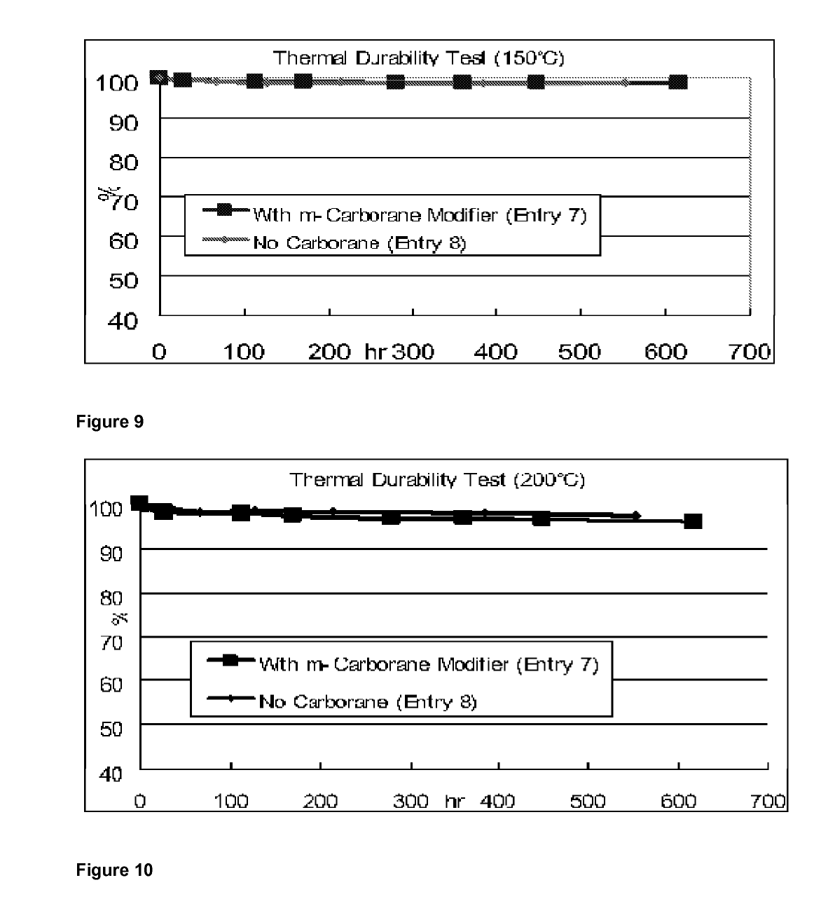

Hydrothermal durability tests of the resins were conducted at 150° C., 200° C., and 60° C./95% RH, respectively. (FIGS. 9 to 11 and Table 2). FIG. 9 shows thermal durability test (150° C.) of resins with/without m-Carborane containing modifier. FIG. 10 shows thermal durability test (200° C.) of resins with/without m-Carborane containing modifier. FIG. 11 shows hydrothermal durability test (60° C./95% RH) of resins with/without m-Carborane containing modifier. From these durability tests, m-Carborane containing modifier was found to give no disadvantage in terms of (hydro)thermal durability of the resins themselves.

### UV Durability Test

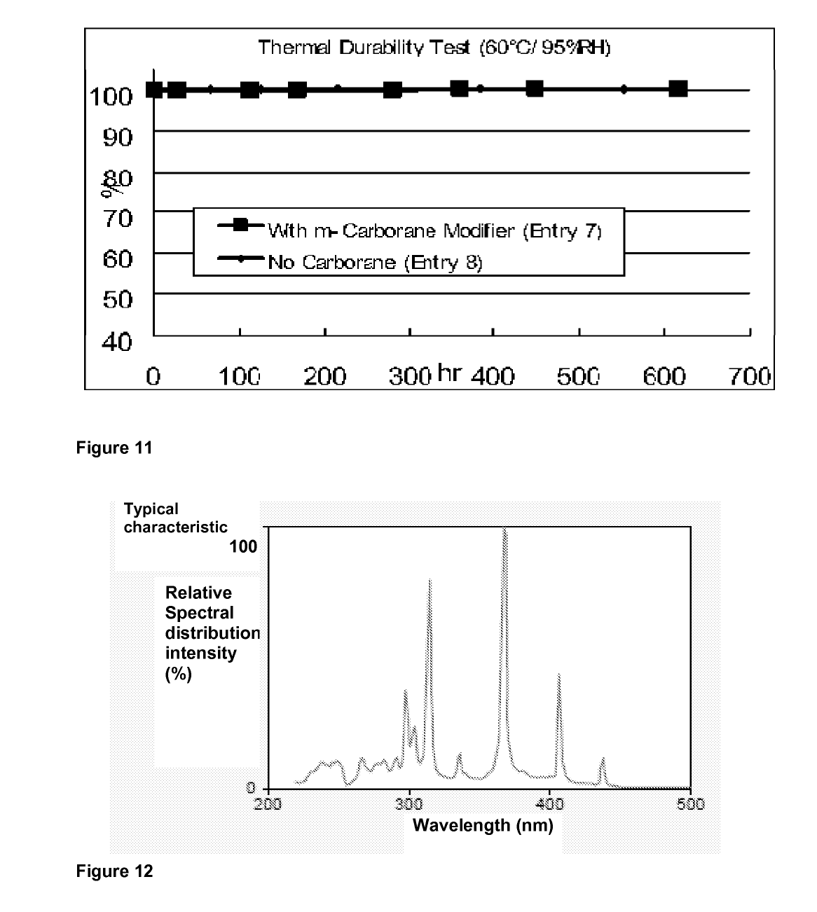

UV durability tests were conducted by irradiating UV light of 2100 mW/cm² for 20 hours. (The spectrum of the original UV light source is shown in FIG. 12. The light below 350 nm was cut off using light-cut-filter.)

Both resins from Entry 7 and 8 (see Table 2) showed no coloration or crack which means these polyorganosiloxanes are highly UV durable.

### Moisture-Reflow Test

Moisture-Reflow test was conducted using LED packages with Ag surface, Ceramic surface, and Polyphthalamide (PPA) surface, respectively.

The resins from Entry 7 and 8 (see Table 2), and those resins blended with Thixotropic agent (fumed silica) were potted into the each LED package and cured by using the heat condition of 150° C.*3 hr+170° C.*2 hr.

Potted LED packages were kept under 60° C./90% RH for 24 hours and then heated on a reflow pan (260° C.) for 5 minutes.

Surprisingly enough, regardless of the presence of the Thixotropic agent, the resin with m-Carborane (Entry 7) gave much better adhesiveness torward PPA surface than the resin without m-Carborane (Entry 8). And Entry 7 resin showed no delamination from the PPA surface.

In cases of Ag and Ceramic LED packages, resins from Entry 7 and 8 gave the same results and none of the resins were delaminated during the Moisture-Reflow test.

### Heat-Cycle Test

Heat-Cycle tests were performed using LED packages with Ag surface, Ceramic surface, and Polyphthalamide (PPA) surface as were used in the Moisture-Reflow test.

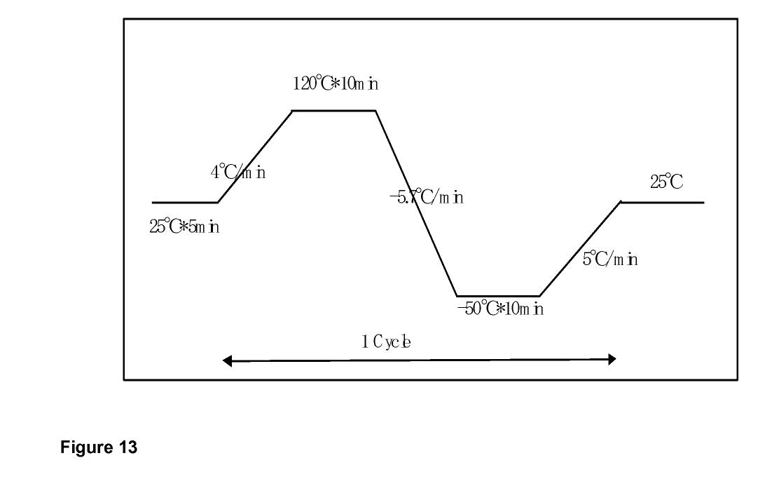

Regardless of the presence of the Thixotropic agent, both of the resins from Entry 7 and 8 gave no delamination up to 300 cycles. (The heating-cooling profile is depicted in FIG. 13.).

### Examples of the Compositions' Application to the Actual Semiconductor (LED) Devices

Performances as LED Encapsulants of the Polyorganosiloxane Compositions Obtained in the Examples above were Evaluated.

LED Life Test

LED Life tests were conducted using LED packages with Ag surface. Life test conditions were 25° C./55% RH and 60° C./90% RH.

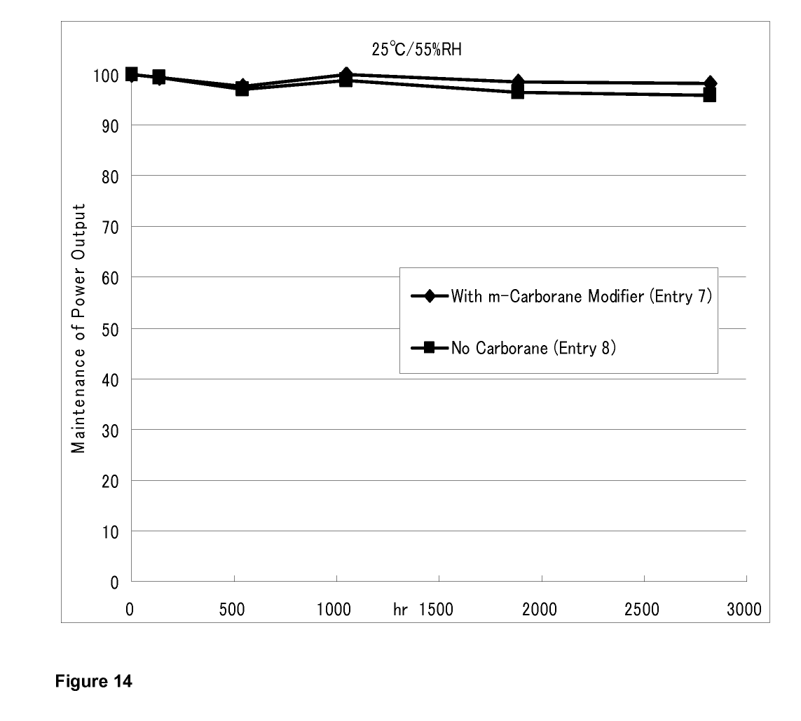

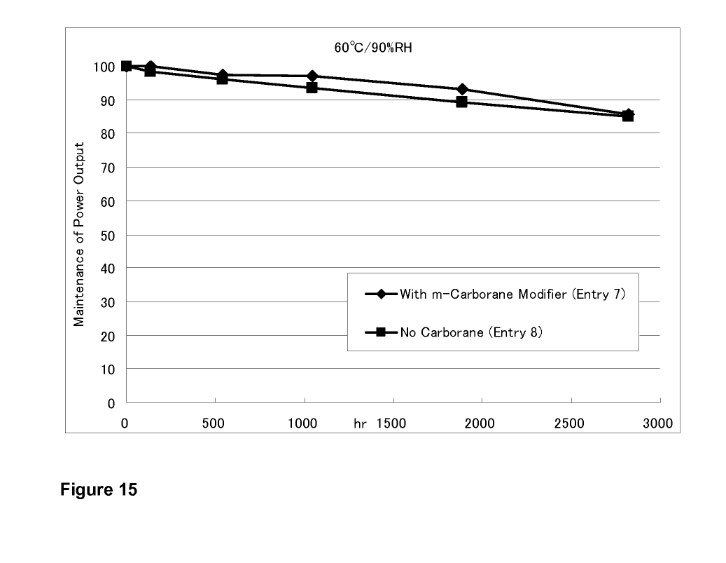

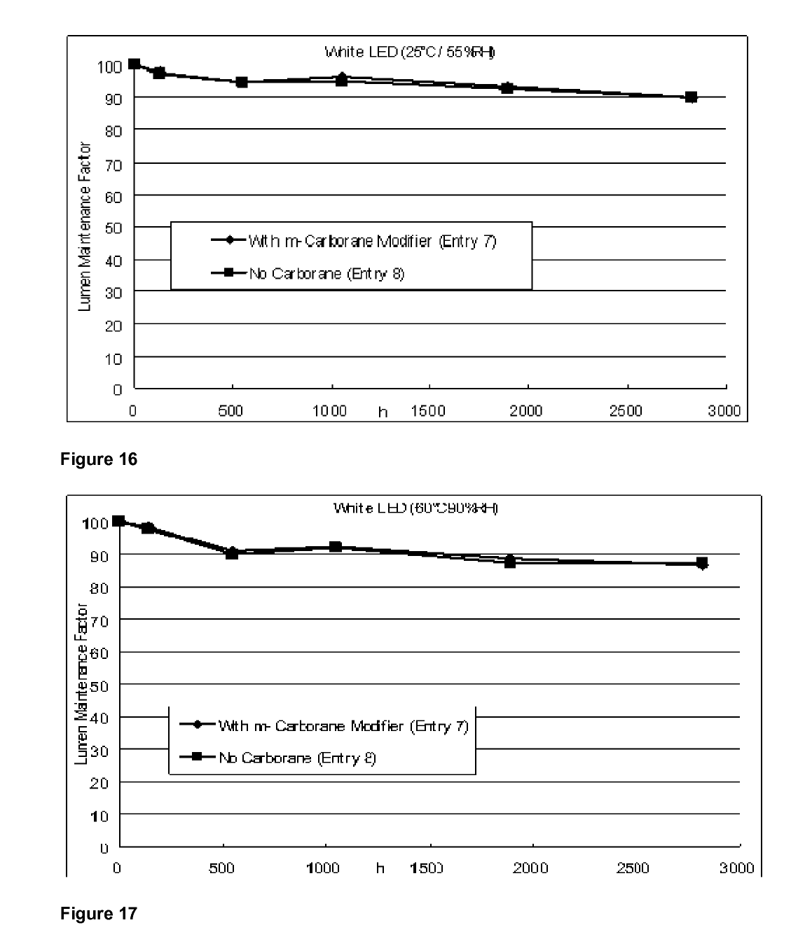

FIGS. 14 and 15 show the power output maintenance factors of the LEDs potted with only resins without phosphors. And FIGS. 16 and 17 show the lumen maintenance factors of the LEDs potted with resins dispersed with RGB phosphors. More specifically, FIG. 14 shows the power output maintenance factor of LEDs without phosphors (25° C./55% RH). And, FIG. 15 shows the power output maintenance factor of LEDs without phosphors (60° C./90% RH). More specifically, FIG. 16 shows the lumen maintenance factor of LEDs with RGB-phosphors (25° C./55% RH). And FIG. 17 shows the lumen maintenance factor of LEDs with RGB-phosphors (60° C./90% RH).

The present application has been described using specific aspects of the invention. Additional descriptions of semiconductor light emitting devices, and LEDs in particular, as well as manufacturing methods therefore, and industrial applicability can be found in detail in WO2006/090804 published Aug. 31, 2006, and also published as EP1854831 (A1), the specification of which is hereby incorporated herein in its entirety.

Although the present invention has been described in connection with the preferred embodiments, it is to be understood that modifications and variations may be utilized without departing from the principles and scope of the invention, as those skilled in the art will readily understand. Accordingly, such modifications may be practiced within the scope of the following claims.

### REFERENCES

1. US Patent Application Publication No. 2004/0063840
2. WIPO Publication No. WO2005/085303
3. Japanese Patent Document: JP-A-2002-203989
4. Japanese Patent Document: JP-A-2004-356506
5. U.S. Pat. No. 5,648,687
6. WIPO Publication No. WO2006/055456
7. U.S. Pat. No. 7,160,972
8. U.S. Pat. No. 6,204,523
9. U.S. Pat. No. 6,590,235
10. U.S. patent application Ser. No. 12/072,891
11. U.S. patent application Ser. No. 12/072,853
12. Japanese Patent Document: JP-Hei 5-25300
13. Hyomen Kagaku, Vol. 18 No. 9, pp 21-26
14. Hyomen Kagaku, Vol. 19 No. 2, pp 44-51
15. WIPO Publication No. WO2008/018981 A2
16. Journal of Polymer Science; Part A: Polymer Chemistry, 2006, 44, 147.
17. Journal of Polymer Science; Part A: Polymer Chemistry, 1998, 36, 1969.
18. Japanese Patent Document: JP-A-2009-19104
19. Japanese Patent Document: JP-A-2009-127020
20. Japanese Patent Document: JP-A-2009-127021
21. Japanese Patent Document: JP-A-2009-127022

1. A semiconductor light emitting device comprising a polysiloxane composition containing a 13^{th} group element of the periodic table,
wherein the polysiloxane composition is obtained by a reaction comprising a compound (A), containing a 13^{th} group element of the periodic table, and a siloxane compound (B).

2. The semiconductor light emitting device as described in claim 1,
wherein the compound (A) is either one or more of a functional carborane, or one or more of the following 2A, 2A′, U, V, W, or W′, or any combination thereof: 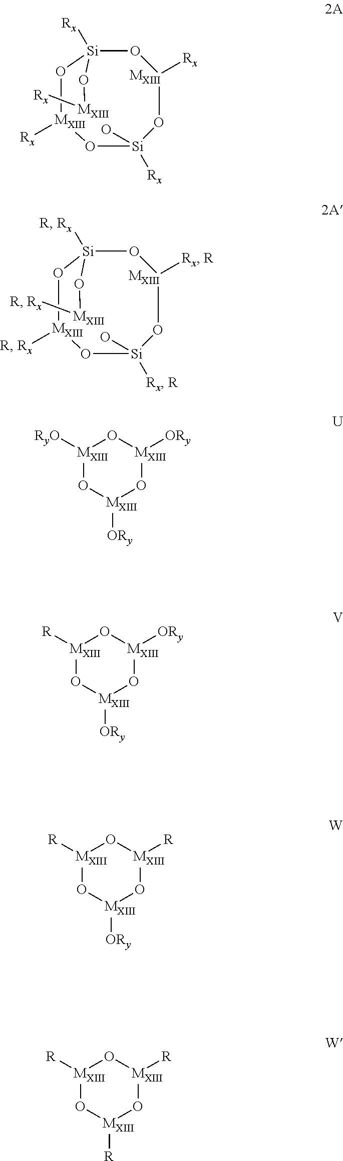
wherein R each independently represents a group selected from hydride, alkyl, alkenyl, aryl, and siloxyl; R_{X} represents an alkenyl or alkynyl group; Ry represents a group selected from hydride, alkyl, alkenyl, and aryl; M_{XIII} represent any 13^{th} group element of the periodic table, where the three M_{XIII} positions have the same element;
wherein for compound 2A′, the notation ‘R, R_{X}’ indicates that there is either one R or R_{X} at the appropriate locations on 2A′; and there must be at least one R_{X} on 2A′, and the remaining ‘R, R_{X}’ positions can be either R or R_{X}.

3. The semiconductor light emitting device as described in claim 1,
wherein the compound (B) is at least one of the compounds represented by the following formulae A′, A″, B, C, X, Y, and Z′: 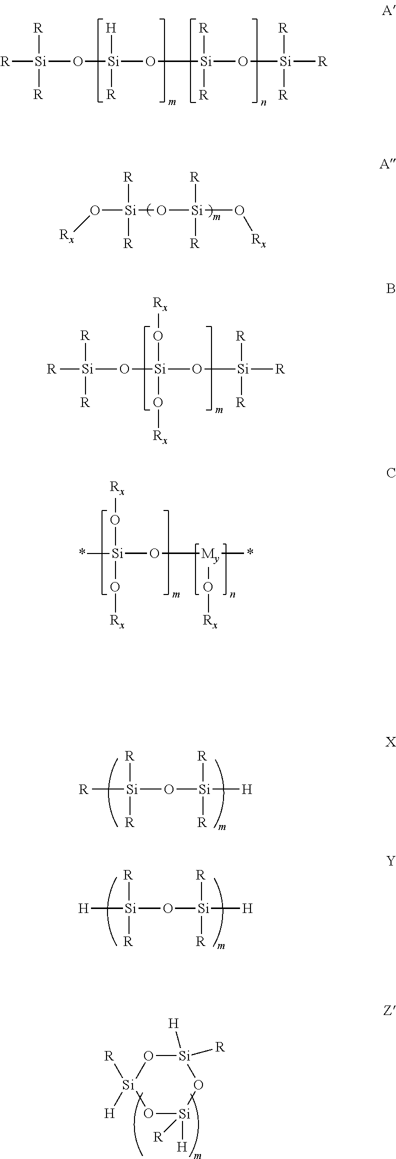
wherein R each independently represents a group selected from hydride, alkyl, alkenyl, aryl, silyl, and a condensable functional group; m is an integer of 1 or more; n is an integer of 0 or more; O—R_{X} represents a condensable hydroxyl group or alkoxyl group; and My in structure C represents a 4^{th} or 13^{th} group element of the periodic table.

4. The semiconductor light emitting device as described in claim 1, wherein the siloxane compound (B) contains a 4^{th} group element of the periodic table.
